(19) United States
(12) Patent Application Publication
(10) Pub. No.: US 2019/0392846 A1
(43) Pub. Date: Dec. 26, 2019

(54) DEMIXING DATA FOR BACKWARD COMPATIBLE RENDERING OF HIGHER ORDER AMBISONIC AUDIO

(71) Applicant: QUALCOMM Incorporated, San Diego, CA (US)

(72) Inventors: Moo Young Kim, San Diego, CA (US); Dipanjan Sen, Dublin, CA (US); Nils Günther Peters, San Diego, CA (US); Ferdinando Olivieri, San Diego, CA (US)

(21) Appl. No.: 16/450,625

(22) Filed: Jun. 24, 2019

Related U.S. Application Data
(60) Provisional application No. 62/689,593, filed on Jun. 25, 2018.

(51) Int. Cl. G10L 19/008; H03M 7/30; H04S 5/00

(52) U.S. Cl. CPC G10L 19/008; H03M 7/6011; H04S 2420/03; H04S 2420/11; H04S 5/005

(57) ABSTRACT

In general, techniques are described by which to obtain demixing data for backward compatible rendering of higher order ambisonic audio data. A device comprising a memory and one or more processors may be configured to perform the techniques. The memory may store the higher order ambisonic (HOA) audio data. The processor may obtain, from a bitstream, legacy audio data that conforms to a legacy audio format, and obtain, from the bitstream, de-mixing data. The processor(s) may process, based on the de-mixing data, the legacy audio data to obtain the first portion of the HOA audio data. The processor(s) may next obtain, from the bitstream, a second portion of the HOA audio data. The processor(s) may render the first portion and the second portion to obtain a speaker feed. Further, the processor(s) may output the speaker feed to a speaker to reproduce a soundfield represented by the HOA audio data.

This application claims the benefit of U.S. Provisional Application Ser. No. 62/689,593, filed Jun. 25, 2018, the entire contents of which are incorporated by reference as if set forth in their entirety herein.

### TECHNICAL FIELD

This disclosure relates to processing of audio data, and specifically to rendering of audio data.

### BACKGROUND

A higher order ambisonic (HOA) signal (often represented by a plurality of spherical harmonic coefficients (SHC) or other hierarchical elements) is a three-dimensional (3D) representation of a soundfield. The HOA or SHC representation may represent this soundfield in a manner that is independent of the local speaker geometry used to playback a multi-channel audio signal rendered from this SHC signal. The SHC signal may also facilitate backwards compatibility as the SHC signal may be rendered to well-known and highly adopted multi-channel formats, such as a 5.1 audio channel format or a 7.1 audio channel format. The SHC representation may therefore enable a better representation of a soundfield that also accommodates backward compatibility.

### SUMMARY

This disclosure relates generally to auditory aspects of the user experience of computer-mediated reality systems, including virtual reality (VR), mixed reality (MR), augmented reality (AR), computer vision, and graphics systems. The techniques may enable rendering of higher-order ambisonic (HOA) audio data for VR, MR, AR, etc. that allows for configurable generation of backward compatible audio signals that conform to legacy audio formats. That is, the HOA audio encoder may expose one or more parameters that can be adapted to produce backward compatible audio signals capable of being reproduced by legacy playback systems (e.g., audio playback systems that are configured to present stereo audio signals).

The techniques may expose these parameters and produce a bitstream with improved backward compatibility (in terms of user perception) without reducing bandwidth allocated to the underlying soundfield (e.g., the bits allocated for representing the compressed version of the HOA audio data). In this respect, the techniques may enable better (in terms of user perception) audio playback for legacy audio playback systems, thereby improving the operation of the audio playback systems themselves.

In one example, the techniques are directed to a device configured to process a bitstream representative of higher order ambisonic audio data, the device comprising: one or more memories configured to store the higher order ambisonic audio data; and one or more processors configured to: obtain, from a bitstream, legacy audio data that conforms to a legacy audio format; obtain, from the bitstream, one or more parameters that identify how the legacy audio data was obtained from the higher order ambisonic audio data; process, based on the one or more parameters, the legacy audio data to obtain a first portion of the higher order ambisonic audio data; obtain, from the bitstream, a second portion of the higher order ambisonic audio data; render the first portion of the higher order ambisonic audio data and the second portion of the higher order ambisonic audio data to obtain one or more speaker feeds; and output the one or more speaker feeds to one or more speakers to reproduce a soundfield represented by the higher order ambisonic audio data.

In another example, the techniques are directed to a method of processing a bitstream representative of higher order ambisonic audio data, the method comprising: obtaining, from the bitstream, legacy audio data that conforms to a legacy audio format; obtaining, from the bitstream, one or more parameters that identify how the legacy audio data was obtained from the higher order ambisonic audio data; processing, based on the one or more parameters, the legacy audio data to obtain a first portion of the higher order ambisonic audio data; obtaining, from the bitstream, a second portion of the higher order ambisonic audio data; rendering the first portion of the higher order ambisonic audio data and the second portion of the higher order ambisonic audio data to obtain one or more speaker feeds; and outputting the one or more speaker feeds to one or more speakers.

In another example, the techniques are directed to a device configured to process a bitstream representative of higher order ambisonic audio data, the device comprising: means for obtaining, from the bitstream, legacy audio data that conforms to a legacy audio form; means for obtaining, from the bitstream, one or more parameters that identify how the legacy audio data was obtained from the higher order ambisonic audio data; means for processing, based on the one or more parameters, the legacy audio data to obtain a first portion of the higher order ambisonic audio data; means for obtaining, from the bitstream, a second portion of the higher order ambisonic audio data; means for rendering the first portion of the higher order ambisonic audio data and the second portion of the higher order ambisonic audio data to obtain one or more speaker feeds; and means for outputting the one or more speaker feeds to one or more speakers.

In another example, the techniques are directed to a non-transitory computer-readable storage medium having stored thereon instructions that, when executed, cause one or more processors to obtain, from a bitstream representative of higher order ambisonic audio data, legacy audio data that conforms to a legacy audio format; obtain, from the bitstream, one or more parameters that identify how the legacy audio data was obtained from the higher order ambisonic audio data; process, based on the one or more parameters, the legacy audio data to obtain a first portion of the higher order ambisonic audio data; obtain, from the bitstream, a second portion of the higher order ambisonic audio data; render the first portion of the higher order ambisonic audio data and the second portion of the higher order ambisonic audio data to obtain one or more speaker feeds; and output the one or more speaker feeds to one or more speakers to reproduce a soundfield represented by the higher order ambisonic audio data.

In another example, the techniques are directed to a device configured to obtain a bitstream representative of higher order ambisonic audio data, the device comprising: one or more memories configured to store the higher order ambisonic audio data; and one or more processors configured to: obtain one or more parameters that identify how legacy audio data that conforms to a legacy audio format is to be obtained from the higher order ambisonic audio data; obtain, from a first portion the higher order ambisonic audio data and based on the one or more parameters, the legacy audio data; specify, in the bitstream that includes a second portion of the higher order ambisonic audio data, the legacy audio data and the one or more parameters; and output the bitstream.

In another example, the techniques are directed to a method of obtaining a bitstream representative of higher order ambisonic audio data, the method comprising: obtaining one or more parameters that identify how legacy audio data that conforms to a legacy audio format is to be obtained from the higher order ambisonic audio data; obtaining, from a first portion the higher order ambisonic audio data and based on the one or more parameters, the legacy audio data; specifying, in the bitstream that includes a second portion of the higher order ambisonic audio data, the legacy audio data and the one or more parameters; and outputting the bitstream.

In another example, the techniques are directed to a device configured to obtain a bitstream representative of higher order ambisonic audio data, the device comprising: means for obtaining one or more parameters that identify how legacy audio data that conforms to a legacy audio format is to be obtained from the higher order ambisonic audio data; means for obtaining, from a first portion the higher order ambisonic audio data and based on the one or more parameters, the legacy audio data; means for specifying, in the bitstream that includes a second portion of the higher order ambisonic audio data, the legacy audio data and the one or more parameters; and means for outputting the bitstream.

In another example, the techniques are directed to a non-transitory computer-readable storage medium having stored thereon instructions that, when executed, cause one or more processors to obtain one or more parameters that identify how legacy audio data that conforms to a legacy audio format is to be obtained from the higher order ambisonic audio data; obtain, from a first portion the higher order ambisonic audio data and based on the one or more parameters, the legacy audio data; specify, in the bitstream that includes a second portion of the higher order ambisonic audio data, the legacy audio data and the one or more parameters; and output the bitstream.

In another example, the techniques are directed to a device configured to process a bitstream representative of higher order ambisonic audio data, the device comprising: one or more memories configured to store the higher order ambisonic audio data; and one or more processors configured to: obtain, from a bitstream, legacy audio data that conforms to a legacy audio format; obtain, from the bitstream, de-mixing data that indicates how to process the legacy audio data to obtain a first portion of the higher order ambisonic audio data; process, based on the de-mixing data, the legacy audio data to obtain the first portion of the higher order ambisonic audio data; obtain, from the bitstream, a second portion of the higher order ambisonic audio data; render the first portion of the higher order ambisonic audio data and the second portion of the higher order ambisonic audio data to obtain one or more speaker feeds; and output the one or more speaker feeds to one or more speakers to reproduce a soundfield represented by the higher order ambisonic audio data.

In another example, the techniques are directed to a method of processing a bitstream representative of higher order ambisonic audio data, the method comprising: obtaining, from the bitstream, legacy audio data that conforms to a legacy audio format; obtaining, from the bitstream, de-mixing data that indicates how to recover a first portion of the higher order ambisonic audio data form the legacy audio data; processing, based on the de-mixing data, the legacy audio data to obtain the first portion of the higher order ambisonic audio data; obtaining, from the bitstream, a second portion of the higher order ambisonic audio data; rendering the first portion of the higher order ambisonic audio data and the second portion of the higher order ambisonic audio data to obtain one or more speaker feeds; and outputting the one or more speaker feeds to one or more speakers.

In another example, the techniques are directed to a device configured to process a bitstream representative of higher order ambisonic audio data, the device comprising: means for obtaining, from the bitstream, legacy audio data that conforms to a legacy audio form; means for obtaining, from the bitstream, de-mixing data that indicates how to process the legacy audio data to obtain a first portion of the higher order ambisonic audio data; means for processing, based on the de-mixing data, the legacy audio data to obtain a first portion of the higher order ambisonic audio data; means for obtaining, from the bitstream, a second portion of the higher order ambisonic audio data; means for rendering the first portion of the higher order ambisonic audio data and the second portion of the higher order ambisonic audio data to obtain one or more speaker feeds; and means for outputting the one or more speaker feeds to one or more speakers.

In another example, the techniques are directed to a non-transitory computer-readable storage medium having stored thereon instructions that, when executed, cause one or more processors to obtain, from a bitstream representative of higher order ambisonic audio data, legacy audio data that conforms to a legacy audio format; obtain, from the bitstream, de-mixing data that indicates how to process the legacy audio data to obtain a first portion of the higher order ambisonic audio data; process, based on the de-mixing data, the legacy audio data to obtain the first portion of the higher order ambisonic audio data; obtain, from the bitstream, a second portion of the higher order ambisonic audio data; render the first portion of the higher order ambisonic audio data and the second portion of the higher order ambisonic audio data to obtain one or more speaker feeds; and output the one or more speaker feeds to one or more speakers to reproduce a soundfield represented by the higher order ambisonic audio data.

In another example, the techniques are directed to a device configured to obtain a bitstream representative of higher order ambisonic audio data, the device comprising: one or more memories configured to store the higher order ambisonic audio data; and one or more processors configured to: obtain mixing data that indicates how to process a first portion of the higher order ambisonic audio data to obtain legacy audio data; process, based on the mixing data, the first portion of the higher order ambisonic audio data to obtain the legacy audio data; obtain de-mixing data that indicates how to process the legacy audio data to obtain the first portion of the higher order ambisonic audio data; specify, in the bitstream that includes a second portion of the higher order ambisonic audio data, the legacy audio data and the de-mixing data; and output the bitstream.

In another example, the techniques are directed to a method of obtaining a bitstream representative of higher order ambisonic audio data, the method comprising: obtaining mixing data that indicates how to process a first portion of the higher order ambisonic audio data to obtain legacy audio data; processing, based on the mixing data, the first portion of the higher order ambisonic audio data to obtain the legacy audio data; obtaining de-mixing data that indicates how to process the legacy audio data to obtain the first portion of the higher order ambisonic audio data; specifying, in the bitstream that includes a second portion of the higher order ambisonic audio data, the legacy audio data and the de-mixing data; and outputting the bitstream.

In another example, the techniques are directed to a device configured to obtain a bitstream representative of higher order ambisonic audio data, the device comprising: means for obtaining mixing data that indicates how to process a first portion of the higher order ambisonic audio data to obtain legacy audio data; means for processing, based on the mixing data, the first portion of the higher order ambisonic audio data to obtain the legacy audio data; means for obtaining de-mixing data that indicates how to process the legacy audio data to obtain the first portion of the higher order ambisonic audio data; means for specifying, in the bitstream that includes a second portion of the higher order ambisonic audio data, the legacy audio data and the de-mixing data; and means for outputting the bitstream.

In another example, the techniques are directed to a non-transitory computer-readable storage medium having stored thereon instructions that, when executed, cause one or more processors to obtain mixing data that indicates how to process a first portion of higher order ambisonic audio data to obtain legacy audio data; process, based on the mixing data, the first portion of the higher order ambisonic audio data to obtain the legacy audio data; obtain de-mixing data that indicates how to process the legacy audio data to obtain the first portion of the higher order ambisonic audio data; specify, in the bitstream that includes a second portion of the higher order ambisonic audio data, the legacy audio data and the de-mixing data; and output the bitstream.

The details of one or more examples of this disclosure are set forth in the accompanying drawings and the description below. Other features, objects, and advantages of various aspects of the techniques will be apparent from the description and drawings, and from the claims.

### BRIEF DESCRIPTION OF DRAWINGS

FIG. 1 is a diagram illustrating spherical harmonic basis functions of various orders and sub-orders.

FIG. 2 is a diagram illustrating a system, including a psychoacoustic audio encoding device, that may perform various aspects of the techniques described in this disclosure.

FIGS. 3A-3D are block diagrams illustrating various aspects of the system of FIG. 2 in more detail.

FIG. 4 is a block diagram illustrating an example of the psychoacoustic audio encoders shown in the examples of FIGS. 3A-3D configured to perform various aspects of the techniques described in this disclosure.

FIG. 5 is a block diagram illustrating an implementation of the psychoacoustic audio decoder of FIGS. 3A-3D in more detail.

FIGS. 6A-6C are diagrams illustrating how an example stereo spread parameter impacts the resulting legacy audio data in accordance with various aspects of the techniques described in this disclosure.

FIGS. 7A-7D are diagrams illustrating how an example beam character parameter impacts the resulting legacy audio data in accordance with various aspects of the techniques described in this disclosure.

FIGS. 8A and 8B are diagrams illustrating how example angle offset parameters impacts the resulting legacy audio data in accordance with various aspects of the techniques described in this disclosure.

FIG. 9 is a diagram illustrating various aspects of the spatial audio encoding device of FIG. 2 in perform various aspects of the techniques described in this disclosure.

FIGS. 10A-10C are diagrams illustrating different representations within the bitstream according to various aspects of the unified data object format techniques described in this disclosure.

FIG. 11 is a block diagram illustrating a different system configured to perform various aspects of the techniques described in this disclosure.

FIG. 12 is a flowchart illustrating example operation of the broadcasting network center of FIG. 1 in performing various aspects of the techniques described in this disclosure.

FIG. 13 is a flowchart illustrating example operation of the audio playback device of FIG. 1 in performing various aspects of the techniques described in this disclosure.

### DETAILED DESCRIPTION

There are various ‘surround-sound’ channel-based formats in the market. They range, for example, from the 5.1 home theatre system (which has been the most successful in terms of making inroads into living rooms beyond stereo) to the 22.2 system developed by NHK (Nippon Hoso Kyokai or Japan Broadcasting Corporation). Content creators (e.g., Hollywood studios, which may also be referred to as content providers) would like to produce the soundtrack for a movie once, and not spend effort to remix it for each speaker configuration. The Moving Pictures Expert Group (MPEG) has released a standard allowing for soundfields to be represented using a hierarchical set of elements (e.g., Higher-Order Ambisonic—HOA—coefficients) that can be rendered to speaker feeds for most speaker configurations, including 5.1 and 22.2 configuration whether in location defined by various standards or in non-uniform locations.

MPEG released the standard as MPEG-H 3D Audio standard, formally entitled “Information technology—High efficiency coding and media delivery in heterogeneous environments—Part 3: 3D audio,” set forth by ISO/IEC JTC 1/SC 29, with document identifier ISO/IEC DIS 23008-3, and dated Jul. 25, 2014. MPEG also released a second edition of the 3D Audio standard, entitled “Information technology—High efficiency coding and media delivery in heterogeneous environments—Part 3: 3D audio, set forth by ISO/IEC JTC 1/SC 29, with document identifier ISO/IEC 23008-3:201x(E), and dated Oct. 12, 2016. Reference to the “3D Audio standard” in this disclosure may refer to one or both of the above standards.

As noted above, one example of a hierarchical set of elements is a set of spherical harmonic coefficients (SHC). The following expression demonstrates a description or representation of a soundfield using SHC:

$${p}_{i} ( t , {r}_{r} , {θ}_{r} , {ϕ}_{r} ) = {\sum }_{ω = 0}^{∞} [ 4 π {\sum }_{n = 0}^{∞} {j}_{n} ( {kr}_{r} ) {\sum }_{m = - n}^{n} {A}_{n}^{m} ( k ) {Y}_{n}^{m} ( {θ}_{r} , {ϕ}_{r} ) ] {e}^{j ω t} ,$$

The expression shows that the pressure pᵢ at any point {rᵣ, θᵣ, φᵣ} of the soundfield, at time t, can be represented uniquely by the SHC, Aₙ^{m}(k). Here,

$$k = \frac{ω}{c} ,$$

c is the speed of sound (˜343 m/s), {rᵣ, θᵣ, φᵣ} is a point of reference (or observation point), jₙ(⋅) is the spherical Bessel function of order n, and Yₙ^{m}(θᵣ,φᵣ) are the spherical harmonic basis functions (which may also be referred to as a spherical basis function) of order n and suborder m. It can be recognized that the term in square brackets is a frequency-domain representation of the signal (i.e., S(ω,rᵣ,θᵣ,φᵣ)) which can be approximated by various time-frequency transformations, such as the discrete Fourier transform (DFT), the discrete cosine transform (DCT), or a wavelet transform. Other examples of hierarchical sets include sets of wavelet transform coefficients and other sets of coefficients of multiresolution basis functions.

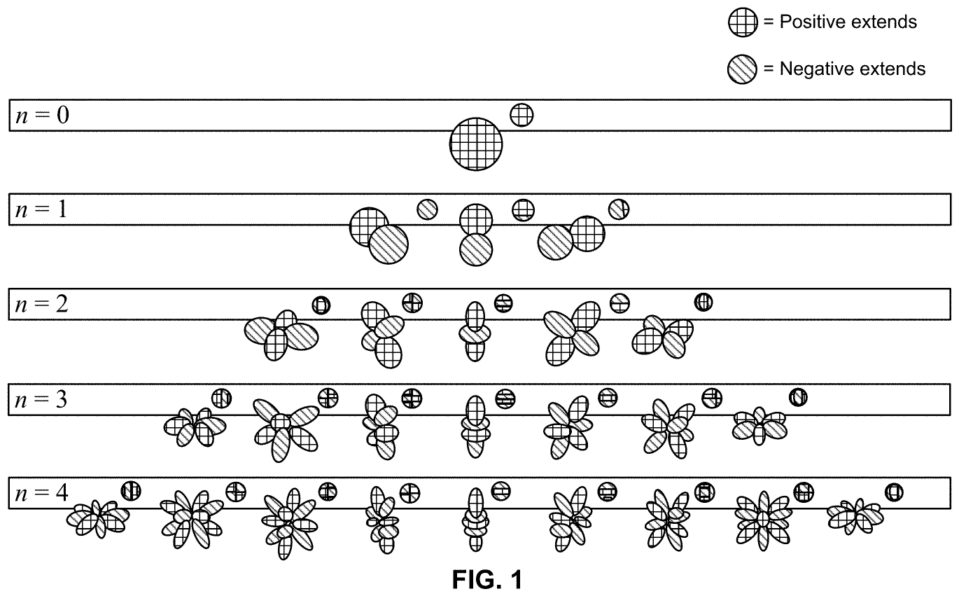

FIG. 1 is a diagram illustrating spherical harmonic basis functions from the zero order (n=0) to the fourth order (n=4). As can be seen, for each order, there is an expansion of suborders m which are shown but not explicitly noted in the example of FIG. 1 for ease of illustration purposes.

The SHC Aₙ^{m}(k) can either be physically acquired (e.g., recorded) by various microphone array configurations or, alternatively, they can be derived from channel-based or object-based descriptions of the soundfield. The SHC (which also may be referred to as higher order ambisonic—HOA—coefficients) represent scene-based audio, where the SHC may be input to an audio encoder to obtain encoded SHC that may promote more efficient transmission or storage. For example, a fourth-order representation involving (1+4)² (25, and hence fourth order) coefficients may be used.

As noted above, the SHC may be derived from a microphone recording using a microphone array. Various examples of how SHC may be derived from microphone arrays are described in Poletti, M., “Three-Dimensional Surround Sound Systems Based on Spherical Harmonics,” J. Audio Eng. Soc., Vol. 53, No. 11, 2005 November, pp. 1004-1025.

To illustrate how the SHCs may be derived from an object-based description, consider the following equation. The coefficients Aₙ^{m}(k) for the soundfield corresponding to an individual audio object may be expressed as:

Aₙ^{m}(k)=g(ω)(−πik)hₙ⁽²⁾(krₛ)Yₙ^{m*}(θₛ,φₛ),

where i is \sqrt{−1}, hₙ⁽²⁾ (⋅) is the spherical Hankel function (of the second kind) of order n, and {rₛ, θₛ, φₛ} is the location of the object. Knowing the object source energy g(ω) as a function of frequency (e.g., using time-frequency analysis techniques, such as performing a fast Fourier transform on the PCM stream) allows us to convert each PCM object and the corresponding location into the SHC Aₙ^{m}(k). Further, it can be shown (since the above is a linear and orthogonal decomposition) that the Aₙ^{m}(k) coefficients for each object are additive. In this manner, a number of PCM objects can be represented by the Aₙ^{m}(k) coefficients (e.g., as a sum of the coefficient vectors for the individual objects). Essentially, the coefficients contain information about the soundfield (the pressure as a function of 3D coordinates), and the above represents the transformation from individual objects to a representation of the overall soundfield, in the vicinity of the observation point {rᵣ, θᵣ, φᵣ}. The remaining figures are described below in the context of SHC-based audio coding.

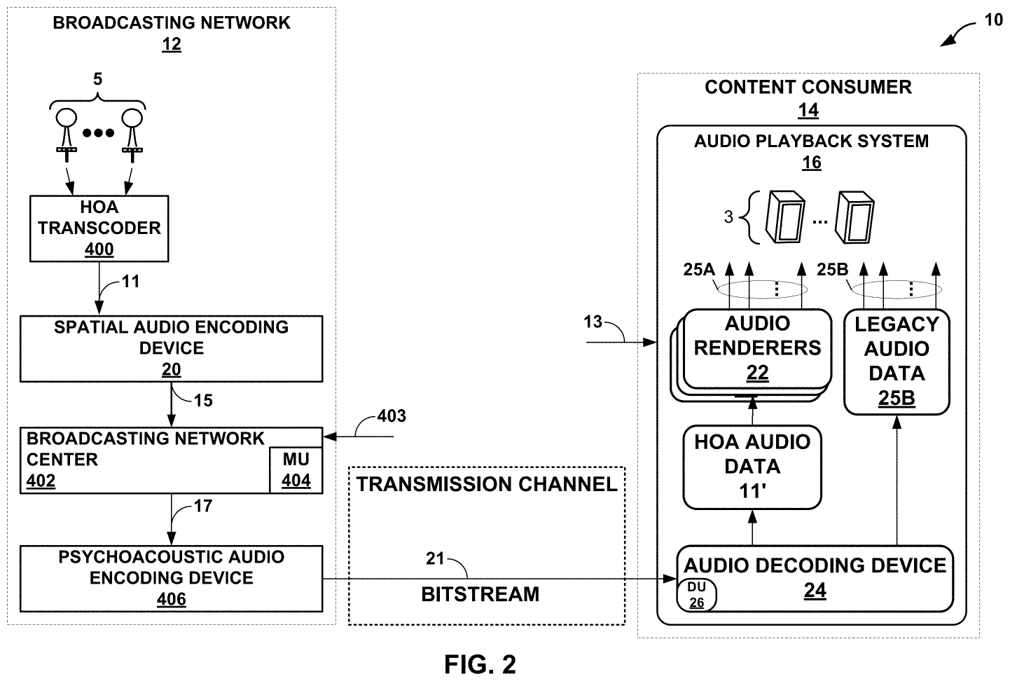

FIG. 2 is a diagram illustrating a system 10 that may perform various aspects of the techniques described in this disclosure. As shown in the example of FIG. 2, the system 10 includes a broadcasting network 12 and a content consumer 14. While described in the context of the broadcasting network 12 and the content consumer 14, the techniques may be implemented in any context in which SHCs (which may also be referred to as HOA coefficients) or any other hierarchical representation of a soundfield are encoded to form a bitstream representative of the audio data.

Moreover, the broadcasting network 12 may represent a system comprising one or more of any form of computing devices capable of implementing the techniques described in this disclosure, including a handset (or cellular phone, including a so-called “smart phone”), a tablet computer, a laptop computer, a desktop computer, or dedicated hardware to provide a few examples. Likewise, the content consumer 14 may represent any form of computing device capable of implementing the techniques described in this disclosure, including a handset (or cellular phone, including a so-called “smart phone”), a tablet computer, a television, a set-top box, a laptop computer, a gaming system or console, or a desktop computer to provide a few examples.

The broadcasting network 12 may represent any entity that may generate multi-channel audio content and possibly video content for consumption by content consumers, such as the content consumer 14. The broadcasting network 12 may represent one example of a content provider. The broadcasting network 12 may capture live audio data at events, such as sporting events, while also inserting various other types of additional audio data, such as commentary audio data, commercial audio data, intro or exit audio data and the like, into the live audio content.

The content consumer 14 represents an individual that owns or has access to an audio playback system, which may refer to any form of audio playback system capable of rendering higher order ambisonic audio data (which includes higher order audio coefficients that, again, may also be referred to as spherical harmonic coefficients) for play back as multi-channel audio content. The higher-order ambisonic audio data may be defined in the spherical harmonic domain and rendered or otherwise transformed form the spherical harmonic domain to a spatial domain, resulting in the multi-channel audio content. In the example of FIG. 2, the content consumer 14 includes an audio playback system 16.

The broadcasting network 12 includes microphones 5 that record or otherwise obtain live recordings in various formats (including directly as HOA coefficients) and audio objects. When the microphone array 5 (which may also be referred to as “microphones 5”) obtains live audio directly as HOA coefficients, the microphones 5 may include an HOA transcoder, such as an HOA transcoder 400 shown in the example of FIG. 2. In other words, although shown as separate from the microphones 5, a separate instance of the HOA transcoder 400 may be included within each of the microphones 5 so as to naturally transcode the captured feeds into the HOA coefficients 11. However, when not included within the microphones 5, the HOA transcoder 400 may transcode the live feeds output from the microphones 5 into the HOA coefficients 11. In this respect, the HOA transcoder 400 may represent a unit configured to transcode microphone feeds and/or audio objects into the HOA coefficients 11. The broadcasting network 12 therefore includes the HOA transcoder 400 as integrated with the microphones 5, as an HOA transcoder separate from the microphones 5 or some combination thereof.

The broadcasting network 12 may also include a spatial audio encoding device 20, a broadcasting network center 402 (which may also be referred to as a “network operations center”—NOC—402) and a psychoacoustic audio encoding device 406. The spatial audio encoding device 20 may represent a device capable of performing the mezzanine compression techniques described in this disclosure with respect to the HOA coefficients 11 to obtain intermediately formatted audio data 15 (which may also be referred to as “mezzanine formatted audio data 15”). Intermediately formatted audio data 15 may represent audio data that conforms with an intermediate audio format (such as a mezzanine audio format). As such, the mezzanine compression techniques may also be referred to as intermediate compression techniques.

The spatial audio encoding device 20 may be configured to perform this intermediate compression (which may also be referred to as “mezzanine compression”) with respect to the HOA coefficients 11 by performing, at least in part, a decomposition (such as a linear decomposition, including a singular value decomposition, eigenvalue decomposition, KLT, etc.) with respect to the HOA coefficients 11. Furthermore, the spatial audio encoding device 20 may perform the spatial encoding aspects (excluding the psychoacoustic encoding aspects) to generate a bitstream conforming to the above referenced MPEG-H 3D audio coding standard. In some examples, the spatial audio encoding device 20 may perform the vector-based aspects of the MPEG-H 3D audio coding standard.

Although described in this disclosure with respect to a bitstream, such as a bitstream having multiple, or in other words, a plurality of transport channels, the techniques may be performed with respect to any type of data object. A data object may refer to any type of formatted data, including the aforementioned bitstream as well as files having multiple tracks, or other types of data objects.

The spatial audio encoding device 20 may be configured to encode the HOA coefficients 11 using a decomposition involving application of a linear invertible transform (LIT). One example of the linear invertible transform is referred to as a “singular value decomposition” (or “SVD”), which may represent one form of a linear decomposition. In this example, the spatial audio encoding device 20 may apply SVD to the HOA coefficients 11 to determine a decomposed version of the HOA coefficients 11.

The decomposed version of the HOA coefficients 11 may include one or more sound components (which may refer to, as one example, an audio object defined in a spatial domain) and/or one or more corresponding spatial components. The sound components having corresponding spatial components may also be referred to as predominant audio signals, or predominant sound components. The sound components may also refer to ambisonic audio coefficients selected from the HOA coefficients 11. While the predominant sound components may be defined in the spatial domain, the spatial component may be defined in the spherical harmonic domain. The spatial component may represent a weighted summation of two or more directional vectors defining shapes, width, and directions of the associated predominant audio signals (which may be referred to in the MPEG-H 3D audio coding standard as a “V-vector”).

The spatial audio encoding device 20 may then analyze the decomposed version of the HOA coefficients 11 to identify various parameters, which may facilitate reordering of the decomposed version of the HOA coefficients 11. The spatial audio encoding device 20 may reorder the decomposed version of the HOA coefficients 11 based on the identified parameters, where such reordering, as described in further detail below, may improve coding efficiency given that the transformation may reorder the HOA coefficients across frames of the HOA coefficients (where a frame commonly includes M samples of the HOA coefficients 11 and M is, in some examples, set to 1024).

After reordering the decomposed version of the HOA coefficients 11, the spatial audio encoding device 20 may select those of the decomposed version of the HOA coefficients 11 representative of foreground (or, in other words, distinct, predominant or salient) components of the soundfield. The spatial audio encoding device 20 may specify the decomposed version of the HOA coefficients 11 representative of the foreground components as an audio object (which may also be referred to as a “predominant sound signal,” or a “predominant sound component”) and associated spatial information (which may also be referred to as a spatial component).

The spatial audio encoding device 20 may next perform a soundfield analysis with respect to the HOA coefficients 11 in order to, at least in part, identify the HOA coefficients 11 representative of one or more background (or, in other words, ambient) components of the soundfield. The spatial audio encoding device 20 may perform energy compensation with respect to the background components given that, in some examples, the background components may only include a subset of any given sample of the HOA coefficients 11 (e.g., such as those corresponding to zero and first order spherical basis functions and not those corresponding to second or higher order spherical basis functions). When order-reduction is performed, in other words, the spatial audio encoding device 20 may augment (e.g., add/subtract energy to/from) the remaining background HOA coefficients of the HOA coefficients 11 to compensate for the change in overall energy that results from performing the order reduction.

The spatial audio encoding device 20 may perform a form of interpolation with respect to the foreground directional information (which again may be another way to refer to the spatial components) and then perform an order reduction with respect to the interpolated foreground directional information to generate order reduced foreground directional information. The spatial audio encoding device 20 may further perform, in some examples, a quantization with respect to the order reduced foreground directional information, outputting coded foreground directional information. In some instances, this quantization may comprise a scalar/entropy quantization.

The spatial audio encoding device 20 may then output the mezzanine formatted audio data 15 as the background components, the foreground audio objects, and the quantized directional information. Each of the background components and the foreground audio objects may be specified in the bitstream as separate pulse code modulated (PCM) transport channels in some examples. Each of the quantized directional information corresponding to each of the foreground audio objects may be specified in the bitstream as sideband information (which may not, in some examples, undergo subsequent psychoacoustic audio encoding/compression to preserve the spatial information). The mezzanine formatted audio data 15 may represent one example of a data object (in the form, in this instance, of a bitstream), and as such may be referred to as a mezzanine formatted data object 15 or mezzanine formatted bitstream 15.

The spatial audio encoding device 20 may then transmit or otherwise output the mezzanine formatted audio data 15 to the broadcasting network center 402. Although not shown in the example of FIG. 2, further processing of the mezzanine formatted audio data 15 may be performed to accommodate transmission from the spatial audio encoding device 20 to the broadcasting network center 402 (such as encryption, satellite compression schemes, fiber compression schemes, etc.).

Mezzanine formatted audio data 15 may represent audio data that conforms to a so-called mezzanine format, which is typically a lightly compressed (relative to end-user compression provided through application of psychoacoustic audio encoding to audio data, such as MPEG surround, MPEG-AAC, MPEG-USAC or other known forms of psychoacoustic encoding) version of the audio data. Given that broadcasters prefer dedicated equipment that provides low latency mixing, editing, and other audio and/or video functions, broadcasters are reluctant to upgrade the equipment given the cost of such dedicated equipment.

To accommodate the increasing bitrates of video and/or audio and provide interoperability with older or, in other words, legacy equipment that may not be adapted to work on high definition video content or 3D audio content, broadcasters have employed this intermediate compression scheme, which is generally referred to as “mezzanine compression,” to reduce file sizes and thereby facilitate transfer times (such as over a network or between devices) and improved processing (especially for older legacy equipment). In other words, this mezzanine compression may provide a more lightweight version of the content which may be used to facilitate editing times, reduce latency and potentially improve the overall broadcasting process.

The broadcasting network center 402 may therefore represent a system responsible for editing and otherwise processing audio and/or video content using an intermediate compression scheme to improve the work flow in terms of latency. The broadcasting network center 402 may, in some examples, include a collection of mobile devices. In the context of processing audio data, the broadcasting network center 402 may, in some examples, insert intermediately formatted additional audio data into the live audio content represented by the mezzanine formatted audio data 15. This additional audio data may comprise commercial audio data representative of commercial audio content (including audio content for television commercials), television studio show audio data representative of television studio audio content, intro audio data representative of intro audio content, exit audio data representative of exit audio content, emergency audio data representative of emergency audio content (e.g., weather warnings, national emergencies, local emergencies, etc.) or any other type of audio data that may be inserted into mezzanine formatted audio data 15.

In some examples, the broadcasting network center 402 includes legacy audio equipment capable of processing up to 16 audio channels. In the context of 3D audio data that relies on HOA coefficients, such as the HOA coefficients 11, the HOA coefficients 11 may have more than 16 audio channels (e.g., a 4^{th} order representation of the 3D soundfield would require (4+1)² or 25 HOA coefficients per sample, which is equivalent to 25 audio channels). This limitation in legacy broadcasting equipment may slow adoption of 3D HOA-based audio formats, such as that set forth in the ISO/IEC DIS 23008-3:201x(E) document, entitled “Information technology—High efficiency coding and media delivery in heterogeneous environments—Part 3: 3D audio,” by ISO/IEC JTC 1/SC 29/WG 11, dated 2016 Oct. 12 (which may be referred to herein as the “3D Audio Coding Standard” or the “MPEG-H 3D Audio Coding Standard”).

As such, the mezzanine compression allows for obtaining the mezzanine formatted audio data 15 from the HOA coefficients 11 in a manner that overcomes the channel-based limitations of legacy audio equipment. That is, the spatial audio encoding device 20 may be configured to obtain the mezzanine audio data 15 having 16 or fewer audio channels (and possibly as few as 6 audio channels given that legacy audio equipment may, in some examples, allow for processing 5.1 audio content, where the ‘0.1’ represents the sixth audio channel).

The broadcasting network center 402 may output updated mezzanine formatted audio data 17. The updated mezzanine formatted audio data 17 may include the mezzanine formatted audio data 15 and any additional audio data inserted into the mezzanine formatted audio data 15 by the broadcasting network center 404. Prior to distribution, the broadcasting network 12 may further compress the updated mezzanine formatted audio data 17. As shown in the example of FIG. 2, the psychoacoustic audio encoding device 406 may perform psychoacoustic audio encoding (e.g., any one of the examples described above) with respect to the updated mezzanine formatted audio data 17 to generate a bitstream 21. The broadcasting network 12 may then transmit the bitstream 21 via a transmission channel to the content consumer 14.

In some examples, the psychoacoustic audio encoding device 406 may represent multiple instances of a psychoacoustic audio coder, each of which is used to encode a different audio object or HOA channel of each of updated mezzanine formatted audio data 17. In some instances, this psychoacoustic audio encoding device 406 may represent one or more instances of an advanced audio coding (AAC) encoding unit. Often, the psychoacoustic audio coder unit 40 may invoke an instance of an AAC encoding unit for each channel of the updated mezzanine formatted audio data 17.

More information regarding how the background spherical harmonic coefficients may be encoded using an AAC encoding unit can be found in a convention paper by Eric Hellerud, et al., entitled “Encoding Higher Order Ambisonics with AAC,” presented at the 124^{th} Convention, 2008 May 17-20 and available at: http://ro.uow.edu.au/cgi/viewcontent.cgi?article=8025&context=engpapers. In some instances, the psychoacoustic audio encoding device 406 may audio encode various channels (e.g., background channels) of the updated mezzanine formatted audio data 17 using a lower target bitrate than that used to encode other channels (e.g., foreground channels) of the updated mezzanine formatted audio data 17.

While shown in FIG. 2 as being directly transmitted to the content consumer 14, the broadcasting network 12 may output the bitstream 21 to an intermediate device positioned between the broadcasting network 12 and the content consumer 14. The intermediate device may store the bitstream 21 for later delivery to the content consumer 14, which may request this bitstream. The intermediate device may comprise a file server, a web server, a desktop computer, a laptop computer, a tablet computer, a mobile phone, a smart phone, or any other device capable of storing the bitstream 21 for later retrieval by an audio decoder. The intermediate device may reside in a content delivery network capable of streaming the bitstream 21 (and possibly in conjunction with transmitting a corresponding video data bitstream) to subscribers, such as the content consumer 14, requesting the bitstream 21. Alternately, the intermediate device may reside within broadcasting network 12.

Alternatively, the broadcasting network 12 may store the bitstream 21 to a storage medium as a file, such as a compact disc, a digital video disc, a high definition video disc or other storage media, most of which are capable of being read by a computer and therefore may be referred to as computer-readable storage media or non-transitory computer-readable storage media. In this context, the transmission channel may refer to those channels by which content stored to these mediums are transmitted (and may include retail stores and other store-based delivery mechanism). In any event, the techniques of this disclosure should not therefore be limited in this respect to the example of FIG. 2. As a file, the transport channels to which various aspects of the decomposed version of the HOA coefficients 11 are stored may be referred to as tracks.

As further shown in the example of FIG. 2, the content consumer 14 includes the audio playback system 16. The audio playback system 16 may represent any audio playback system capable of playing back multi-channel audio data. The audio playback system 16 may include a number of different audio renderers 22. The audio renderers 22 may each provide for a different form of rendering, where the different forms of rendering may include one or more of the various ways of performing vector-base amplitude panning (VBAP), and/or one or more of the various ways of performing soundfield synthesis. As used herein, “A and/or B” means “A or B”, or both “A and B”.

In some instances, the audio playback system 16 may include a legacy audio playback system that is capable of reproducing soundfields from audio data (including audio signals) that conforms to a legacy audio format. Examples of legacy audio formats include a stereo audio format (having a left channel and a right channel), a stereo audio format plus (having, in addition to the left and right channels, a low frequency effects channel), a 5.1 surround sound format (having front left and front right channels, a center channel, back left and right channels, and a low frequency effects channel), etc.

The audio playback system 16 may further include an audio decoding device 24. The audio decoding device 24 may represent a device configured to decode HOA coefficients 11′ (which may also be referred to as HOA audio data 11′) from the bitstream 21, where the HOA audio data 11′ may be similar to the HOA coefficients 11 (which may also be referred to as HOA audio data 11) but differ due to lossy operations (e.g., quantization) and/or noise injected during transmission via the transmission channel.

That is, the audio decoding device 24 may dequantize the foreground directional information specified in the bitstream 21, while also performing psychoacoustic decoding with respect to the foreground audio objects specified in the bitstream 21 and the encoded HOA coefficients representative of background components. The audio decoding device 24 may further perform interpolation with respect to the decoded foreground directional information and then determine the HOA coefficients representative of the foreground components based on the decoded foreground audio objects and the interpolated foreground directional information. The audio decoding device 24 may then determine the HOA audio data 11′ based on the determined HOA coefficients representative of the foreground components and the decoded HOA coefficients representative of the background components.

The audio playback system 16 may, after decoding the bitstream 21 to obtain the HOA audio data 11′, render the HOA audio data 11′ to output speaker feeds 25A. The audio playback system 15 may output speaker feeds 25A to one or more of speakers 3. The speaker feeds 25A may drive one or more loudspeakers 3.

To select the appropriate renderer or, in some instances, generate an appropriate renderer, the audio playback system 16 may obtain speaker information 13 indicative of a number of loudspeakers and/or a spatial geometry of the loudspeakers. In some instances, the audio playback system 16 may obtain the loudspeaker information 13 using a reference microphone and driving the speakers (which may include loudspeakers) in such a manner as to dynamically determine the speaker information 13. In other instances, or in conjunction with the dynamic determination of the speaker information 13, the audio playback system 16 may prompt a user to interface with the audio playback system 16 and input the speaker information 13.

The audio playback system 16 may select one of the audio renderers 22 based on the speaker information 13. In some instances, the audio playback system 16 may, when none of the audio renderers 22 are within some threshold similarity measure (in terms of the speaker geometry) to the speaker geometry specified in the speaker information 13, generate the one of audio renderers 22 based on the speaker information 13. The audio playback system 16 may, in some instances, generate one of the audio renderers 22 based on the speaker information 13 without first attempting to select an existing one of the audio renderers 22.

When outputting the speaker feeds 25A to headphones, the audio playback system 16 may utilize one of the renderers 22 that provides for binaural rendering using head-related transfer functions (HRTF) or other functions capable of rendering to left and right speaker feeds 25A for headphone speaker playback. The terms “speakers” or “transducer” may generally refer to any speaker, including loudspeakers, headphone speakers, etc. One or more speakers may then playback the rendered speaker feeds 25A.

Although described as rendering the speaker feeds 25A from the HOA audio data 11′, reference to rendering of the speaker feeds 25A may refer to other types of rendering, such as rendering incorporated directly into the decoding of the HOA audio data 11′ from the bitstream 21. An example of the alternative rendering can be found in Annex G of the MPEG-H 3D audio coding standard, where rendering occurs during the predominant signal formulation and the background signal formation prior to composition of the soundfield. As such, reference to rendering of the HOA audio data 11′ should be understood to refer to both rendering of the actual HOA audio data 11′ or decompositions or representations thereof of the HOA audio data 11′ (such as the above noted predominant audio signal, the ambient HOA coefficients, and/or the vector-based signal—which may also be referred to as a V-vector).

As noted above, the audio playback system 16 may represent a legacy audio playback system that reproduces soundfields only from the above noted legacy audio formats. To allow for backwards compatibility, various ones of audio renderers 22 may render HOA audio data 15 to speaker feeds 25AA that conform to the legacy audio formats. For example, one of renderers 22 may represent a B-format-to-A-format (B2A) converter configured to convert the HOA audio data 15 or a portion thereof to a speaker feeds 25A conforming to the stereo audio format. The B-format refers to a portion of the HOA audio data that includes HOA coefficients corresponding to the first-order and zero-order spherical basis functions, which may also be referred to as a first-order ambisonic (FOA) signal. The A-format denotes the stereo audio format. Although described herein primarily with respect to the stereo audio format, the techniques may be applied with respect to any legacy audio format (being “legacy” in comparison to the recently introduced ambisonics audio format, which may also be referred to as a scene-based audio format).

A number of different B2A converters exist. One example of a B2A converter is the mode matrix set forth in the above referenced MPEG-H 3D Audio Coding Standard. Another example of a B2A converter is a CODVRA converter, which is described in more detail in a document produced by Dolby Laboratories Inc., entitled, “Encoding First-Order Ambisonics with HE-AAC,” and dated Oct. 13, 2017. Yet another converter is UHJ matrix conversion.

As another example, rather than render the A-format from the B-format, the soundfield representation generator 302 may obtain the A-format (either from the content capture device 300 or by rendering the B-format) and specify the A-format in the bitstream 21 in addition to the B-format. This process of specifying both the A-format and the B-format is referred to as simulcasting.

In the above instances, there are a number of deficiencies. B2A converters and simulcasting are both “fixed” in the sense that the B2A conversion is fixed by the selected renderer or by what is provided by the content capture device 300. In other words, the B2A converters and simulcast are fixed in the sense that both are time-invariant and cannot be personalized by the content provider. The fixed nature of the B2A converters and simulcasting may potentially limit the ability of content creators to personalize the stereo mix and deliver a good experience for legacy audio playback systems. Furthermore, simulcasting may reduce bandwidth available for representing the HOA audio data 15 in the bitstream 21, thereby sacrificing a quality of the HOA audio data 15 at the expense of improving the experience for legacy audio playback systems.

In accordance with various aspects of the techniques described in this disclosure, the audio playback system 16 may render the HOA audio data 11′ to speaker feeds 25A in a manner that also allows for configurable generation of backward compatible audio signals 25B (which may also be referred to as speaker feeds 25B) that conform to legacy audio formats. That is, the HOA audio encoder 20 may allocate bits for specifying one or more parameters that can be adapted to produce backward compatible audio signals 25B capable of being reproduced by legacy playback systems (e.g., audio playback systems that are configured to present stereo audio signals).

The techniques may provide these parameters and produce a bitstream 21 with improved backward compatibility (in terms of user perception) without potentially reducing bandwidth allocated to the underlying soundfield (e.g., the bits allocated for representing the compressed version of the HOA audio data). In this respect, the techniques may enable better (in terms of user perception) audio playback for legacy audio playback systems, thereby improving the operation of the audio playback systems themselves.

In operation, the spatial audio encoding device 20 may output the intermediately formatted audio data 15, which may include one or more transport channels specifying the ambient HOA audio data (such as the background HOA coefficients) and any predominant audio signals, and side information that specifies the spatial characteristics of the predominant audio signals (e.g., the above noted V-vectors). The broadcasting network center 402 may obtain the intermediately formatted audio data 15 and extract the ambient HOA audio data (such as the HOA coefficients corresponding to any combination of the zero order spherical basis function—generally denoted by the variable W—and any of the three first order spherical basis functions, which are denoted by the variables X, Y, and Z).

In some instances, the first portion of the higher order ambisonic audio data may include data indicative of a first coefficient corresponding to a zero-order spherical basis function (W). In this and other instances, the first portion of the higher order ambisonic audio data comprises data indicative of a first coefficient corresponding to a zero-order spherical basis function, and a second coefficient corresponding to a first-order spherical basis function.

In any event, as further shown in the example of FIG. 2, the broadcasting unit 402 may include a mixing unit (MU) 404. The mixing unit 404 may represent a unit configured to process the ambient HOA audio data to obtain legacy audio data 25B conforming to a legacy audio format, such as any of the examples listed above and others not listed. The mixing unit 404 may obtain parameters 403 that identify how the legacy audio data 25B is to be obtained from a portion of the higher order ambisonic audio data (e.g., the ambient HOA audio data noted above). A sound engineer or other operator may specify the parameters 403, or the broadcasting network center 402 may apply one or more algorithms that assess the ambient HOA audio data and automatically generate the parameters 403. In any event, the mixing unit 404 may obtain, from the ambient HOA audio data and based on the parameters 403, the legacy audio data 25B.

In some instances, the mixing unit 404 may obtain, based on the parameters 403, mixing data. The mixing data may, as one example, include a mixing matrix, which the mixing unit 404 may apply to the ambient HOA audio data to obtain the legacy audio data 25B. In this way, the mixing unit 404 may process, based on the mixing data, the ambient HOA audio data to obtain the legacy audio data 25B.

The broadcasting network center 402 may specify, in the intermediately formatted audio data 15 (which may also be referred to as the bitstream 15) that includes a second portion of the higher order ambisonic audio data, the legacy audio data 25B and the one or more parameters 403. The second portion of the higher order ambisonic audio data may include a compressed version of one or more additional ambient HOA coefficients, and a compressed version of predominant sound signals along with side information representative of a compressed version of the spatial characteristics. The second portion of the higher order ambisonic audio data may include data representative of one or more coefficients corresponding to spherical basis functions to which one or more coefficients of the first portion of the higher order ambisonic audio data do not correspond (potentially in the form of a predominant audio signal and a corresponding spatial characteristic).

The broadcasting network center 402 may specify the parameters 403 according to the following example syntax table:

| Syntax | No. of bits | Mnemonic |
|---|---|---|
| { | | |
| StereoSpread; | 2 | uimsbf |
| BeamCharacter; | 2 | uimsbf |
| if (beamCharacter==3) {alpha;} | x | uimsbf |
| hasAngleOffset; | 1 | uimsbf |
| if (hasAngleOffset==1) { | | uimsbf |
| azimuthAngleOffset; | 9 | uimsbf |
| elevationAngleOffset; | 9 | uimsbf |
| } | | |
| } | | |

As shown in the foregoing syntax table, the parameters 403 may include a “StereoSpread” syntax element, a “BeamCharacter” syntax element, a “hasAngleOffset” syntax element, an “azimuthAngleOffset” syntax element, and an “elevationAngleOffset” syntax element.

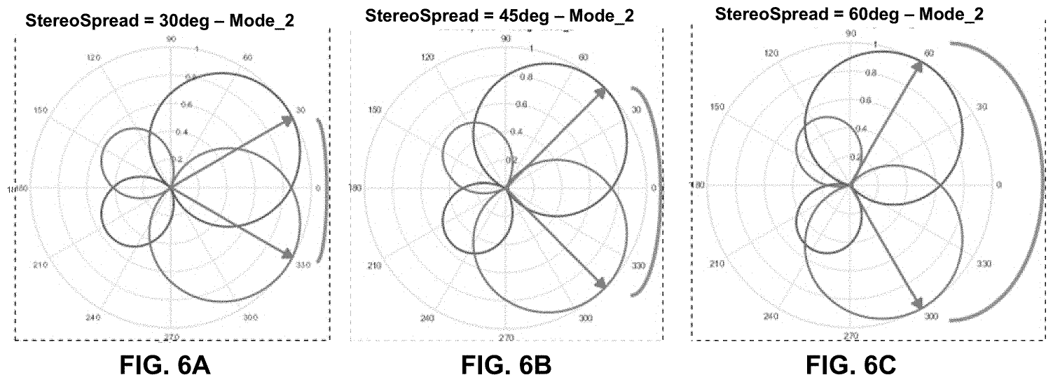

The StereoSpread syntax element may represent a stereo spread parameter that may identify a width between sound sources used when obtaining the legacy audio data 25B. The effect of the stereo spread parameter on obtaining the legacy audio data 25B is shown in more detail with respect to FIGS. 6A-6C.

FIGS. 6A-6C are diagrams illustrating how an example stereo spread parameter impacts the resulting legacy audio data 25B in accordance with various aspects of the techniques described in this disclosure. As shown in FIG. 6A, the stereo spread parameter indicates a 30 degree spread from the 0 degree coordinate, resulting in a 60 degree spread between the left and right stereo channels from the center (which may be referred to as the so-called “sweet spot”). As shown in FIG. 6B, the stereo spread parameter indicates a 45 degree spread from the 0 degree coordinate, resulting in a 90 degree spread between the left and right stereo channels relative to the sweet spot. As shown in FIG. 6C, the stereo spread parameter indicates a 60 degree spread from the 0 degree coordinate, resulting in a 120 degree spread between the left and right stereo channels from the sweet spot.

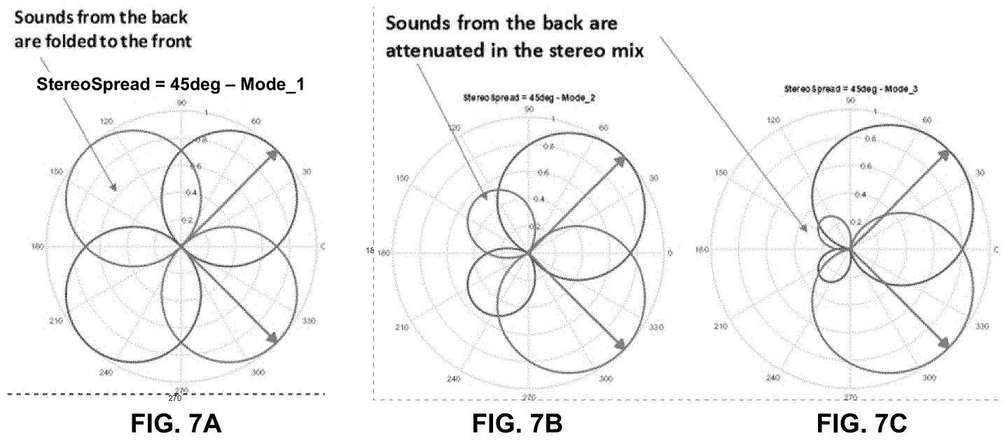

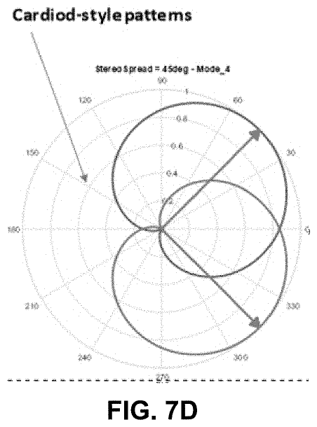

The BeamCharacter syntax element may represent a beam character parameter that identifies a type of virtual microphone beams used for obtaining the legacy audio data 25B. The beam character parameter may identify different levels of attenuation for sounds coming from the rear (or, in other words, back) in reference to the sweet spot. The beam character parameter may define a type of the “virtual microphone beams” used for the stereo mixing. The effect of the beam character parameter on obtaining the legacy audio data 25B is shown in more detail with respect to FIGS. 7A-7D.

FIGS. 7A-7D are diagrams illustrating how an example beam character parameter impacts the resulting legacy audio data 25B in accordance with various aspects of the techniques described in this disclosure. As shown in FIG. 7A, the beam character parameter indicates a first mode, resulting in folding sounds from the back into the front (relative to the sweet spot). As shown in FIGS. 7B and 7C, the beam character parameter indicates a second mode and a third mode respectively, resulting in different levels of attenuation of sounds from the back (relative to the sweet spot). As shown in FIG. 7D, the beam character parameter indicates a fourth mode, resulting in cardiod-style patters.

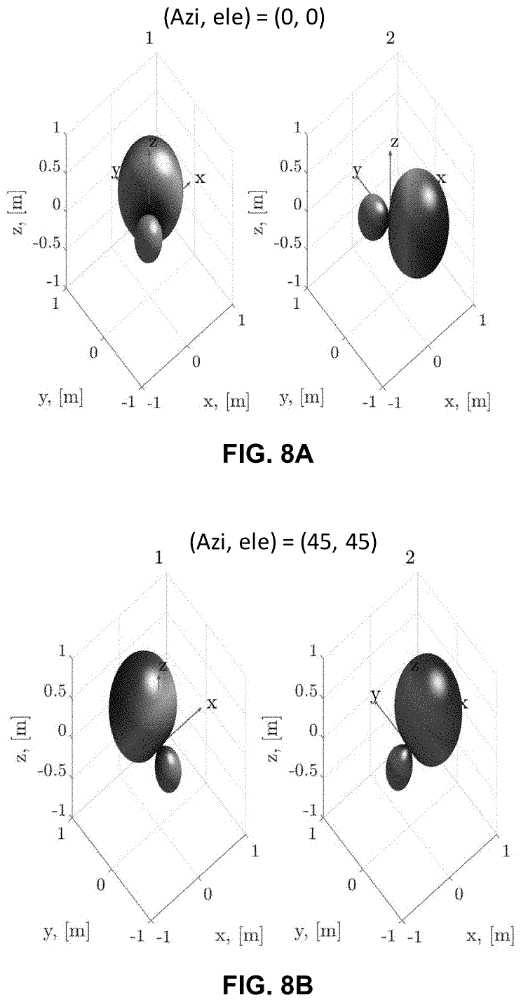

The hasAngleOffset syntax element represents syntax element that indicates whether the azimuthAngleOffset syntax element, and the elevationAngleOffset syntax element are present in the bitstream. Each of the azimuthAngleOffset syntax element and the elevationAngleOffset syntax element may represent an angle offset parameter that identifies an angle (azimuth angle and elevation angle respectively) between sound sources used when obtaining the parameter that identifies a type of virtual microphone beams used for obtaining the legacy audio data 25B. These angle offset parameters may indicates how the beams are “centered” around the azimuth and elevation angles. The effect of the angle offset parameters on obtaining the legacy audio data 25B is shown in more detail with respect to FIGS. 8A and 8B.

FIGS. 8A and 8B are diagrams illustrating how example angle offset parameters impacts the resulting legacy audio data 25B in accordance with various aspects of the techniques described in this disclosure. As shown in the example of FIG. 8A, the azimuth angle offset (denoted as “Azi”) and the elevation angle offset (denoted as “ele”) are set to zero (0) and (0) to provide a frame of reference for understanding the impact on the legacy audio data 25B, as shown in FIG. 8B, of setting the azimuth angle offset to 45 degrees and the elevation angle offset to 45 degrees.

Referring back to the example of FIG. 2, the broadcasting network center 402 may also obtain de-mixing data that indicates how to process the legacy audio data 25B to obtain the ambient HOA audio data. The broadcasting network center 402 may obtain the mixing data from the mixing unit 404, and next determine, based on the mixing data, the de-mixing data. In instances where the mixing data is a mixing matrix, the broadcasting network center 402 may obtain the de-mixing data as an inverse (or pseudo-inverse) of the mixing matrix. The mixing data includes mixing data representative of a mixing matrix that converts M input signals into N output signals, where M does not equal N. The broadcasting network center 402 may specify, in the bitstream 15 that includes the second portion of the audio data, the legacy audio data 25B (as noted above) and the de-mixing data.

The broadcasting network center 402 may specify the de-mixing data as set forth in the following example syntax table:

| Syntax | No. of bits | Mnemonic |
|---|---|---|
| { | | |
| bitDepth = bitDepthIdx + 1; | 4 | uimsbf |
| numRow = rowIdx + 1; | 4 | uimsbf |
| numCol = colIdx + 1; | 4 | uimsbf |
| for i=1:numRow | bitDepth | bslbf |
| for j=1:numCol | | |
| D(i,j); // i-th row and j-th column of de- | | |
| mixing matrix D | | |
| } | | |

As shown in the above syntax table, the de-mixing data (denoted by the matrix “D”) may be specified in terms of a bitDepthIdx syntax element, a rowIdx syntax element, and a colIdx syntax element. The bitDepthIdx may define a bit depth for each matrix coefficient of a de-mixing matrix represented by D. The rowIdx syntax element may identify a number of rows in the de-mixing matrix, while the colIdx syntax element may identify a number of columns in the de-mixing matrix.

Although shown as fully specifying each matrix coefficient for every row and column of the de-mixing matrix referenced in the above syntax table, the broadcasting network center 402 may attempt to reduce the number of matrix coefficients explicitly specified in the bitstream 15 through application of compression that leverages sparseness and/or symmetry properties that may occur in the de-mixing matrix. That is, the de-mix data may include sparseness information indicative of a sparseness of the de-mix matrix, which the broadcast network center 402 may specify in order to signal that various matrix coefficients are not specified in the bitstream 15. More information regarding how the broadcast network center 402 may obtain the sparseness information and thereby reduce the number of matrix coefficients specified in the bitstream 15 can be found in U.S. Pat. No. 9,609,452, entitled “OBTAINING SPARSENESS INFORMATION FOR HIGHER ORDER AMBISONIC AUDIO RENDERERS,” which issued on Mar. 28, 2017.

The de-mix data may also, in some examples and either in conjunction with or as an alternative to sparseness information, include symmetry information that indicates a symmetry of the de-mix matrix, which the broadcast network center 402 may specify in order to signal that various matrix coefficients are not specified in the bitstream 15. The symmetry information may include value symmetry information that indicates value symmetry of the de-mix matrix and/or sign symmetry information that indicates sign symmetry of the de-mix matrix. More information regarding how the broadcast network center 402 may obtain the sparseness information and thereby reduce the number of matrix coefficients specified in the bitstream 15 can be found in U.S. Pat. No. 9,883,310, entitled “OBTAINING SYMMETRY INFORMATION FOR HIGHER ORDER AMBISONIC AUDIO RENDERERS,” which issued on Jan. 30, 2018.

The audio decoding device 24 may obtain the bitstream 21 and perform psychoacoustic audio decoding with respect to the bitstream 21 to obtain the mezzanine formatted audio data 17 (which may again be referred to as the bitstream 17). The audio decoding device 24 may obtain, from the bitstream 17, the legacy audio data 25B that conforms to the legacy audio format. The audio decoding device 24 may next obtain, from the bitstream 17, the parameters 403.

As shown in the example of FIG. 2, the audio decoding device 24 may include a de-mixing unit (DU) 26, which the audio decoding device 24 may invoke to process, based on the parameters 403, the legacy audio data 25B to obtain the ambient HOA audio data. In some instances, the de-mixing unit 26 may obtain, from the bitstream 21, above described de-mixing data that indicates how to process the legacy audio data 25B to obtain the ambient HOA audio data. In some examples, the de-mixing unit 26 may process, based on the parameters 403, the de-mixing data to obtain the de-mixing matrix described above. In this respect, the de-mixing data includes de-mixing data representative of a de-mixing matrix that converts N input signals into M output signals, where N does not equal M. The de-mixing unit 26 may apply the de-mixing matrix to the legacy audio data 25B to obtain the ambient HOA audio data.

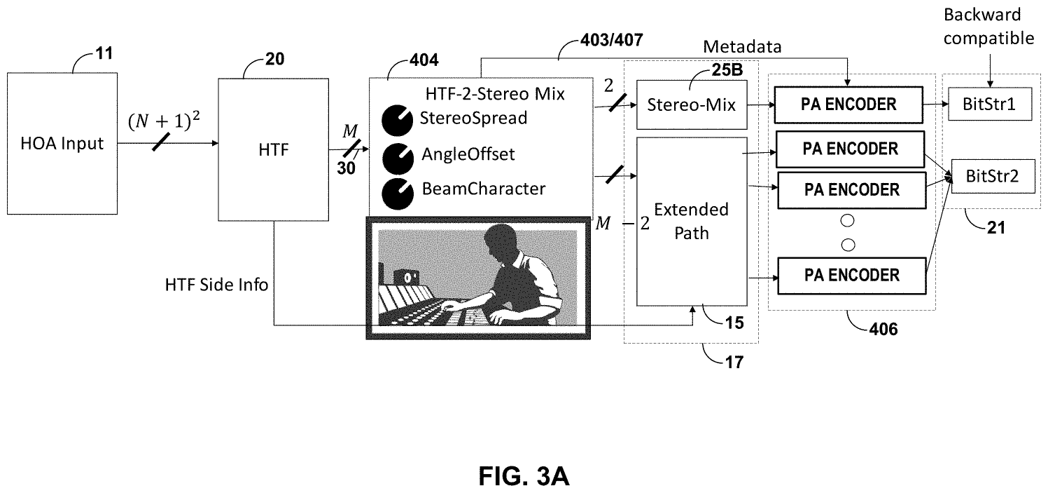

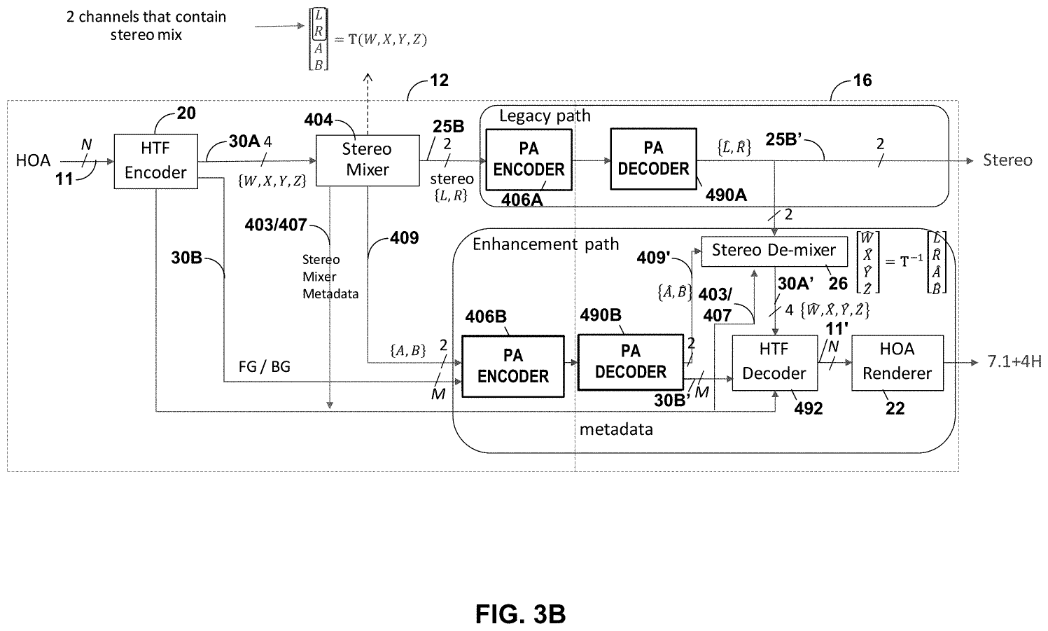

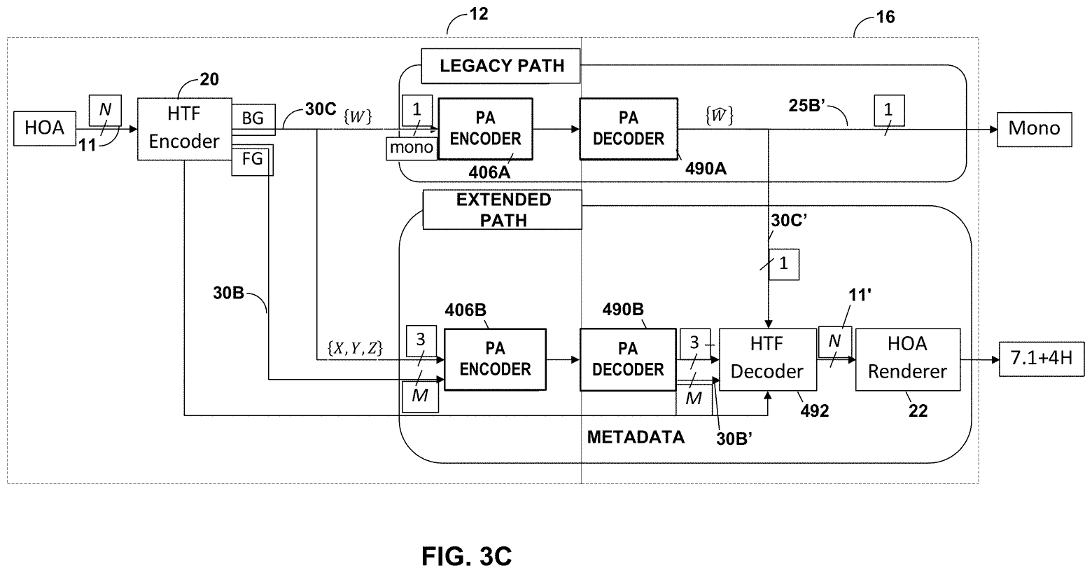

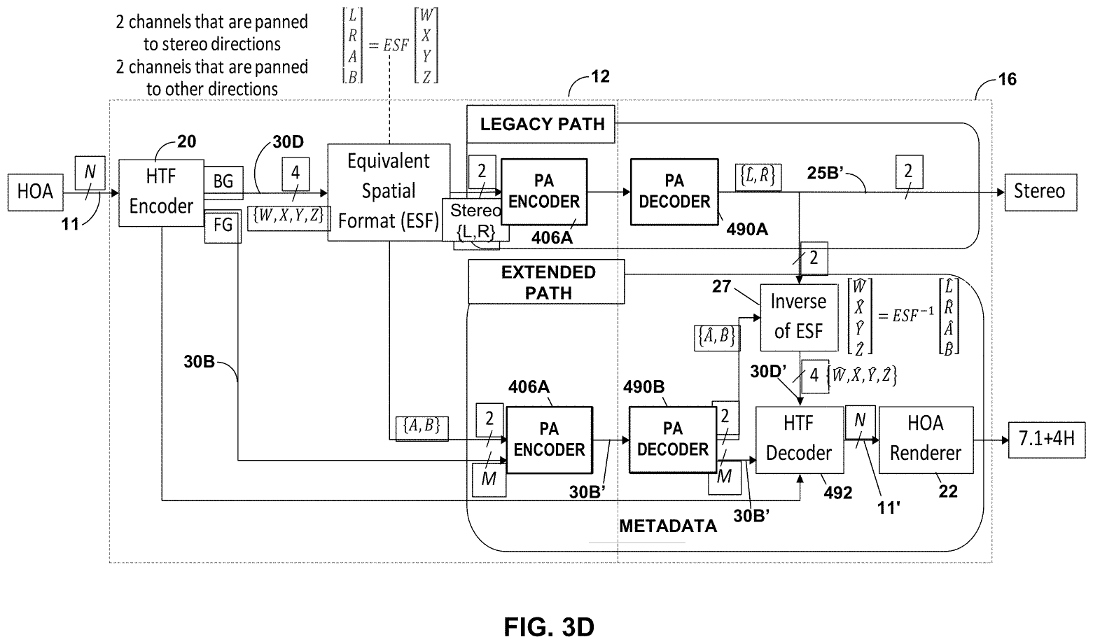

The audio decoding device 24 may also obtain, from the bitstream 17, the second portion of the higher order ambisonic audio data. The audio decoding device 24 may obtain, based on the ambient HOA audio data and the second portion of the higher order ambisonic audio data, the HOA audio data 11′. The audio playback system 16 may then apply one or more of the audio renders 22 to the HOA audio data 11′ to obtain the one or more speaker feeds 25A. The audio playback system 16 may next output the one or more speaker feeds 25A to the one or more speakers 3. More information regarding how the legacy and enhanced processing may proceed is described with respect to FIGS. 3A-3D.

FIGS. 3A-3D are block diagrams illustrating various aspects of the system 10 of FIG. 2 in more detail. As shown in the example of FIG. 3A, the spatial audio encoding device 20 (which may also be referred to as HOA transport format—HTF—device 20 as shown in FIG. 3A) may first obtain HOA audio data 11 (which may also be referred to as HOA input 11 as shown in FIG. 3A). The HTF device 20 may compress the (N+1)² HOA coefficients per sample (where N is italicized to differentiate from N listed above, and refers to the highest order of a spherical basis function to which an HOA coefficient of the HOA input 11 is associated) into M (where M is italicized to differentiate from M listed above) transport channels 30.

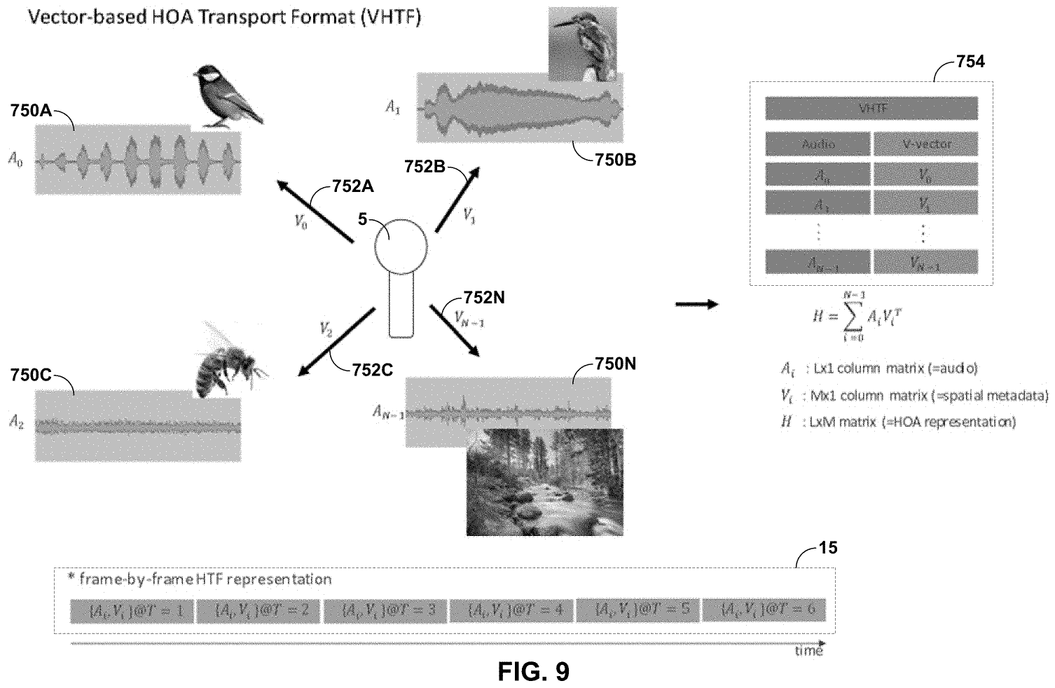

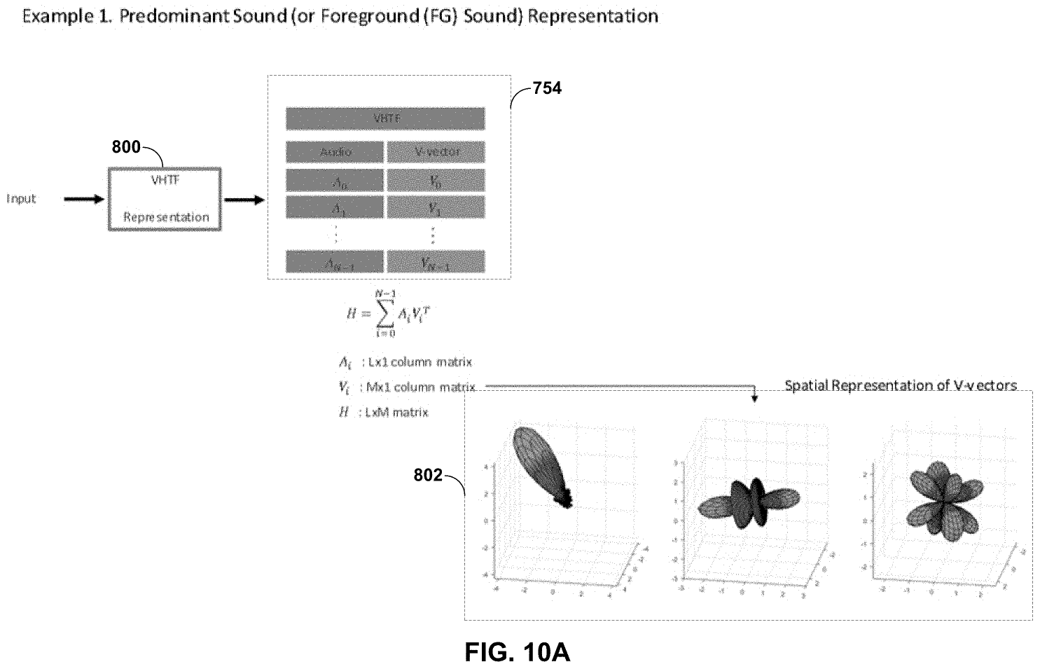

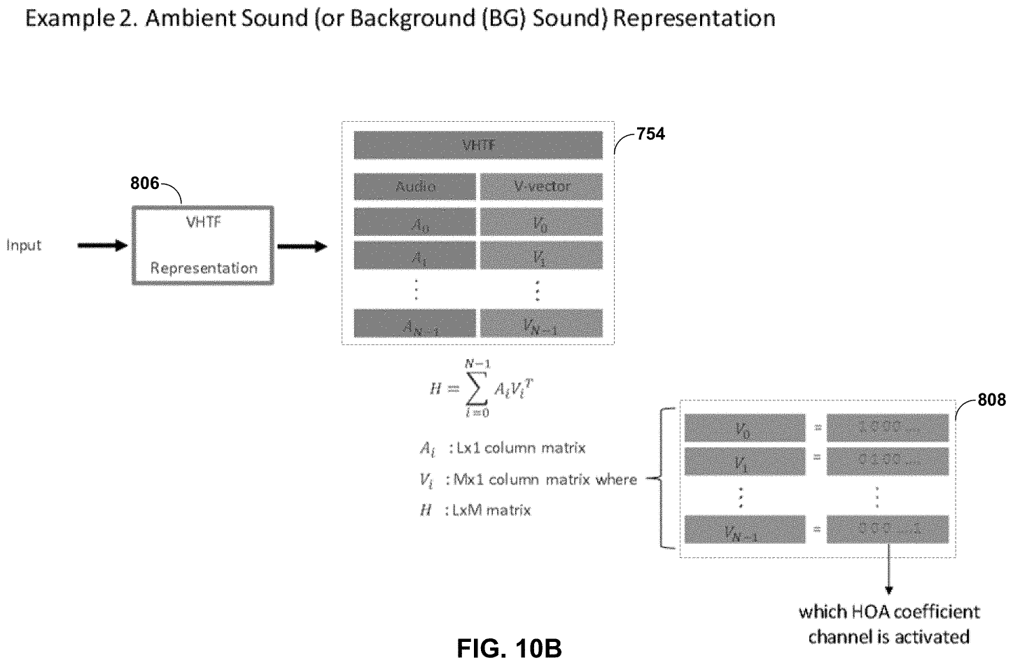

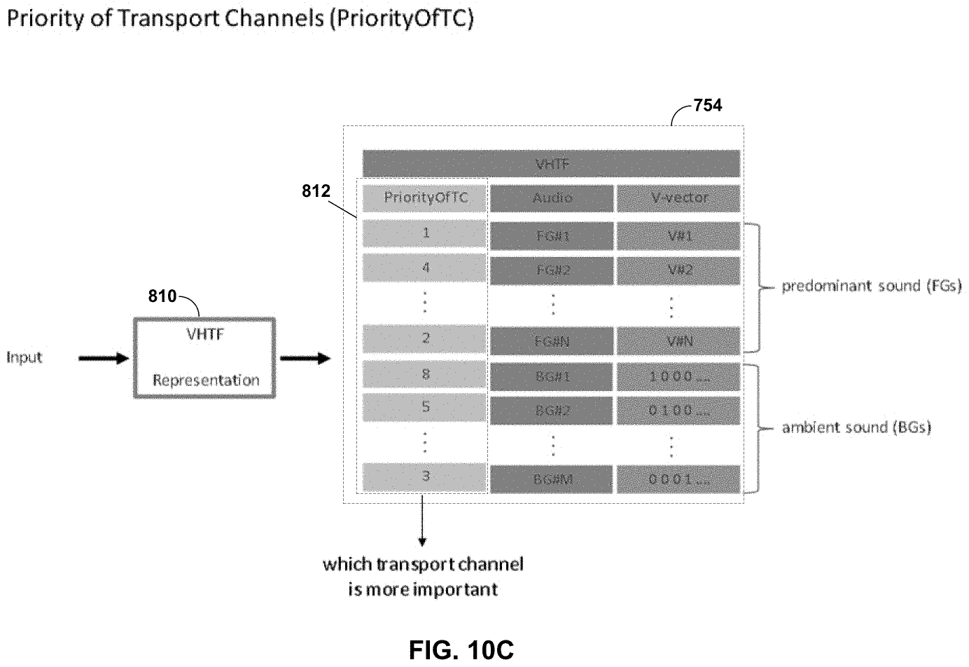

Each transport channel of the M transport channels 30 may specify a single HOA coefficient of the ambient HOA audio data or a predominant audio signal (e.g., an audio object formed by multiplying a U-vector by an S-vector as set forth in the MPEG-H 3D Audio Coding Standard). The HTF device 20 may formulate the bitstream 15 according to various aspects of a Technical Specification (TS), entitled “Higher Order Ambisonics (HOA) Transport Format,” dated June 2018, and published by the European Telecommunication Standards Institute (ETSI) as ETSI TS 103 589 v1.1.1. More information regarding the HOA transport format can be found below with respect to FIGS. 9-10C.

In any event, the HTF device 20 may output the M transport channels 30 to mixing unit 404, which may apply the parameters 403 discussed above to obtain the legacy audio data 25B (which is shown by way of example in FIG. 3A as a “stereo mix”). The mixing unit 404 may output the legacy audio data 25B as two channels (in the example of legacy stereo audio data) to the psychoacoustic audio encoding device 406 as part of the bitstream 17. The mixing unit 404 may further output the second portion of the HOA audio data remaining in the bitstream 15 as M—2 transport channels, thereby forming the bitstream 17. The mixing unit 404 may also specify the parameters 403 and/or de-mixing matrix 407 as metadata 403/407 in the bitstream 21 formulated by the psychoacoustic audio encoding device 406 in the manner described above in more detail.

The psychoacoustic audio (PA) encoding device 406 may, as one example, apply enhanced advanced audio coding (eAAC) with respect to each of the transport channels of the bitstream 17 to obtain the bitstream 21. eAAC may refer to any number of different types of AAC, such as high efficiency AAC (HE-AAC), HE-AACv2 (which is also referred to as aacPlus v2 or eAAC+), and the like.

While described with respect to eAAC and/or AAC, the techniques may be performed using any type of psychoacoustic audio coding that, as described in more detail below, allows for extension packets (such as the below discussed fill elements) or otherwise allows for backward compatibility. Examples of other psychoacoustic audio codecs include Audio Codec 3 (AC-3), Apple Lossless Audio Codec (ALAC), MPEG-4 Audio Lossless Streaming (ALS), aptX®, enhanced AC-3, Free Lossless Audio Codec (FLAC), Monkey's Audio, MPEG-1 Audio Layer II (MP2), MPEG-1 Audio Layer III (MP3), Opus, and Windows Media Audio (WMA).

As shown in the example of FIG. 3B, the HTF encoder 20 (which is another name for the HTF device 20) may process HOA input 11 to obtain four ambient HOA coefficients (shown as W, X, Y, and Z) specified in transport channels 30A, and foreground (FG—such as the predominant audio signals) and background (BG—such as the additional ambient HOA coefficients) components specified in transport channels 30B. The mixing unit 404 (which in this example is a stereo mixing unit) may mix the four ambient HOA coefficients to obtain left and right stereo channels 25B. The mixing unit 404 may also output residual audio data 409 resulting from mixing the four ambient HOA coefficients to form the two stereo legacy audio channels 25B.

The psychoacoustic audio (PA) encoding devices 406A and 406B may perform psychoacoustic audio encoding with respect to the legacy audio data 25B, and the residual audio data 409 and the transport channels 30B to obtain the bitstream 21 in the manner described above in more detail. The psychoacoustic audio encoding devices 406A and 406B may output the bitstream 21 to the audio playback system 16.

The audio playback system 16 may invoke psychoacoustic audio decoding devices 490A and 490B to process the bitstream 21 to obtain the legacy audio data 25B′ (where the prime notation throughout this disclosure denotes the slight changes discussed above), residual audio data 409′, and the transport channels 30B′ in the manner described in more detail above. When the audio playback system 16 has been configured to reproduce the soundfield using legacy audio data 25B′, the audio playback system 16 may output the legacy audio data 25B′ to two stereo speakers 3 (shown as the “Legacy path”).

When the audio playback system 16 has been configured to reproduce the soundfield using enhanced audio data set forth in the transport channels 30B, the audio playback system 16 may invoke HTF decoder 492 (which may represent a unit configure to operate in a manner reciprocal to the HTF encoder 20) to decompress the transport channels 30B′ to obtain the second portion of the HOA audio data 11′. The audio playback device 16 may also invoke the de-mixing unit 26 to process, based on one or more of the parameters 403 and the de-mixing data 407 (which is denoted by the variable T⁻¹, while the mixing matrix is denoted by the variable T), the legacy audio data 25B′ to obtain the four ambient HOA coefficients 30A′. The de-mixing unit 26 may output the four ambient HOA coefficients 30A′ to the HTF decoder 492.

The HTF decoder 492 may obtain, based on the four ambient HOA coefficients 30A′ and the transport channels 30B′, the HOA audio data 11′. The HTF decoder 492 may output the HOA audio data 11′ to one or more of the audio renderers 22 to obtain enhanced audio data that includes a number of different speaker feeds 25A that are then output to the speakers 3 (which are assumed to be arranged in a 7.1 format with four additional speakers that add height to the reproduction of the soundfield—4H).

FIG. 3C illustrates an example in which the transport channel 30C includes only one channel (the ‘W’ channel). As such, the audio data of the transport channel 30C′ is not inverse-mixed or de-mixed in the extended path. For instance, the transport channels 30C and 30C′ carry audio data conforming to a monaural legacy audio format. In the example of FIG. 3C, the transport channels 30C and 30C′ are described as carrying legacy mono audio data. In various use case scenarios, the legacy path of FIG. 3C may also render and output the mono audio data.

FIG. 3D illustrates an example in which the transport channel 30C includes four channels, namely, the channels defined in the set the {W, X, Y, Z}. The example of FIG. 3D provides backward-compatible encoding, decoding, and playback of audio data that includes objects in the HOA domain as well as ‘W’, ‘X’, ‘Y’, and ‘Z’ channels, or an extended spatial format (“ESF”). The legacy path in the example of FIG. 3D mixes two channels that are panned to stereo directions and/or two channels that are panned to other directions at an encoding or pre-encoding stage of any legacy ESF audio data, to produce a mixed left-right signal (shown as a mix of L and R signals). The PA decoder 490A of the legacy path provides the decoded ESV signals (shown as L\hat{ } and R\hat{ }) to an inverse mixing unit 27 positioned in the extended path. The inverse mixing unit 27 may use matrix-multiplication to obtain the ESF channels (a total of four channels in this particular example) 30D′ of the legacy ESF audio data.

Additionally, the HTF decoder 492 of the extended path may supplement the 3D audio data obtained by decoding the HOA-domain audio data of the transport channels 30B′ with the legacy ESF {W\hat{ }, X\hat{ }, Y\hat{ }, Z\hat{ }} channels 30D′ obtained from the inverse mixing unit 27. The HOA renderer 22 may output a combination of the 3D audio data obtained from the decoded HOA-domain audio data of HOA coefficients 11′ and the audio data of the legacy stereo-format ESF {W\hat{ }, X\hat{ }, Y\hat{ }, Z\hat{ }} channels 30D′. In cases of a legacy audio system being incorporated in the illustrated system, the PA decoder 490A may also render and output the legacy ESF audio data, as shown in FIG. 3D.

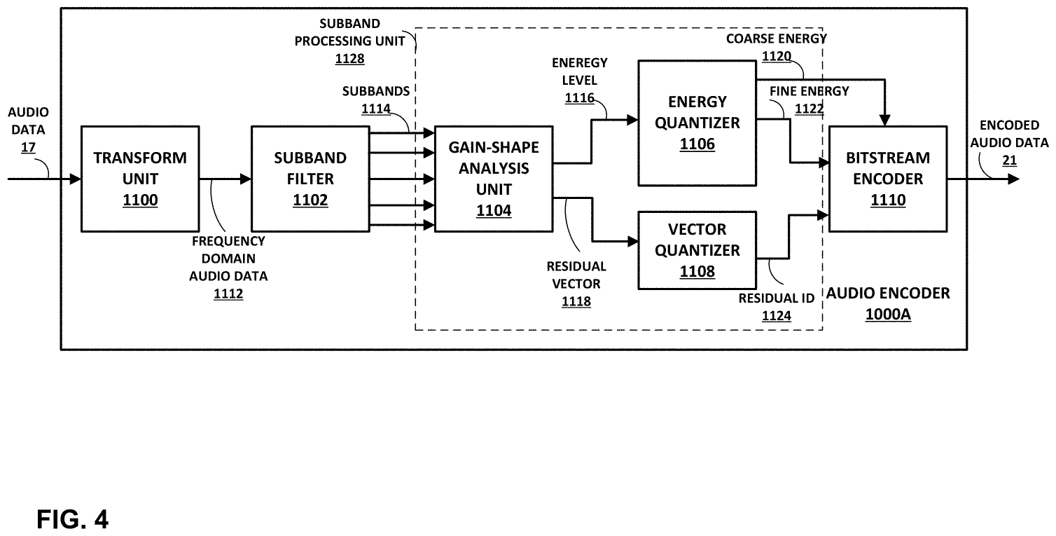

FIG. 4 is a block diagram illustrating an example of the psychoacoustic audio encoders shown in the examples of FIGS. 3A-3D configured to perform various aspects of the techniques described in this disclosure. The audio encoder 1000A may represent one example of AptX encoder, which may be configured to encode audio data for transmission over a personal area network or “PAN” (e.g., Bluetooth®). However, the techniques of this disclosure performed by the audio encoder 1000A may be used in any context where the compression of audio data is desired. In some examples, the audio encoder 1000A may be configured to encode the audio data 17 in accordance with as aptX™ audio codec, including, e.g., enhanced aptX—E-aptX, aptX live, and aptX high definition.

In the example of FIG. 4, the audio encoder 1000A may be configured to encode the audio data 17 using a gain-shape vector quantization encoding process that includes coding residual vector using compact maps. In a gain-shape vector quantization encoding process, the audio encoder 1000A is configured to encode both a gain (e.g., an energy level) and a shape (e.g., a residual vector defined by transform coefficients) of a subband of frequency domain audio data. Each subband of frequency domain audio data represents a certain frequency range of a particular frame of the audio data 17.

The audio data 17 may be sampled at a particular sampling frequency. Example sampling frequencies may include 48 kHz or 44.1 kHZ, though any desired sampling frequency may be used. Each digital sample of the audio data 17 may be defined by a particular input bit depth, e.g., 16 bits or 24 bits. In one example, the audio encoder 1000A may be configured operate on a single channel of the audio data 21 (e.g., mono audio). In another example, the audio encoder 1000A may be configured to independently encode two or more channels of the audio data 17. For example, the audio data 17 may include left and right channels for stereo audio. In this example, the audio encoder 1000A may be configured to encode the left and right audio channels independently in a dual mono mode. In other examples, the audio encoder 1000A may be configured to encode two or more channels of the audio data 17 together (e.g., in a joint stereo mode). For example, the audio encoder 1000A may perform certain compression operations by predicting one channel of the audio data 17 with another channel of the audio data 17.

Regardless of how the channels of the audio data 17 are arranged, the audio encoder 1000A obtains the audio data 17 and sends that audio data 17 to a transform unit 1100. The transform unit 1100 is configured to transform a frame of the audio data 17 from the time domain to the frequency domain to produce frequency domain audio data 1112. A frame of the audio data 17 may be represented by a predetermined number of samples of the audio data. In one example, a frame of the audio data 17 may be 1024 samples wide. Different frame widths may be chosen based on the frequency transform being used and the amount of compression desired. The frequency domain audio data 1112 may be represented as transform coefficients, where the value of each the transform coefficients represents an energy of the frequency domain audio data 1112 at a particular frequency.

In one example, the transform unit 1100 may be configured to transform the audio data 17 into the frequency domain audio data 1112 using a modified discrete cosine transform (MDCT). An MDCT is a “lapped” transform that is based on a type-IV discrete cosine transform. The MDCT is considered “lapped” as it works on data from multiple frames. That is, in order to perform the transform using an MDCT, transform unit 1100 may include a fifty percent overlap window into a subsequent frame of audio data. The overlapped nature of an MDCT may be useful for data compression techniques, such as audio encoding, as it may reduce artifacts from coding at frame boundaries. The transform unit 1100 need not be constrained to using an MDCT but may use other frequency domain transformation techniques for transforming the audio data 17 into the frequency domain audio data 1112.

A subband filter 1102 separates the frequency domain audio data 1112 into subbands 1114. Each of the subbands 1114 includes transform coefficients of the frequency domain audio data 1112 in a particular frequency range. For instance, the subband filter 1102 may separate the frequency domain audio data 1112 into twenty different subbands. In some examples, subband filter 1102 may be configured to separate the frequency domain audio data 1112 into subbands 1114 of uniform frequency ranges. In other examples, subband filter 1102 may be configured to separate the frequency domain audio data 1112 into subbands 1114 of non-uniform frequency ranges.

For example, subband filter 1102 may be configured to separate the frequency domain audio data 1112 into subbands 1114 according to the Bark scale. In general, the subbands of a Bark scale have frequency ranges that are perceptually equal distances. That is, the subbands of the Bark scale are not equal in terms of frequency range, but rather, are equal in terms of human aural perception. In general, subbands at the lower frequencies will have fewer transform coefficients, as lower frequencies are easier to perceive by the human aural system. As such, the frequency domain audio data 1112 in lower frequency subbands of the subbands 1114 is less compressed by the audio encoder 1000A, as compared to higher frequency subbands. Likewise, higher frequency subbands of the subbands 1114 may include more transform coefficients, as higher frequencies are harder to perceive by the human aural system. As such, the frequency domain audio 1112 in data in higher frequency subbands of the subbands 1114 may be more compressed by the audio encoder 1000A, as compared to lower frequency subbands.

The audio encoder 1000A may be configured to process each of subbands 1114 using a subband processing unit 1128. That is, the subband processing unit 1128 may be configured to process each of subbands separately. The subband processing unit 1128 may be configured to perform a gain-shape vector quantization process with extended-range coarse-fine quantization in accordance with techniques of this disclosure.

A gain-shape analysis unit 1104 may receive the subbands 1114 as an input. For each of subbands 1114, the gain-shape analysis unit 1104 may determine an energy level 1116 of each of the subbands 1114. That is, each of subbands 1114 has an associated energy level 1116. The energy level 1116 is a scalar value in units of decibels (dBs) that represents the total amount of energy (also called gain) in the transform coefficients of a particular one of subbands 1114. The gain-shape analysis unit 1104 may separate energy level 1116 for one of subbands 1114 from the transform coefficients of the subbands to produce residual vector 1118. The residual vector 1118 represents the so-called “shape” of the subband. The shape of the subband may also be referred to as the spectrum of the subband.

A vector quantizer 1108 may be configured to quantize the residual vector 1118. In one example, the vector quantizer 1108 may quantize the residual vector using a quantization process to produce the residual ID 1124. Instead of quantizing each sample separately (e.g., scalar quantization), the vector quantizer 1108 may be configured to quantize a block of samples included in the residual vector 1118 (e.g., a shape vector. However, any vector quantization techniques method can be used along with the extended-range coarse-fine energy quantization techniques of this disclosure.

In some examples, the audio encoder 1000A may dynamically allocate bits for coding the energy level 1116 and the residual vector 1118. That is, for each of subbands 1114, the audio encoder 1000A may determine the number of bits allocated for energy quantization (e.g., by the energy quantizer 1106) and the number of bits allocated for vector quantization (e.g., by the vector quantizer 1108). The total number of bits allocated for energy quantization may be referred to as energy-assigned bits. These energy-assigned bits may then be allocated between a coarse quantization process and a fine quantization process.

An energy quantizer 1106 may receive the energy level 1116 of the subbands 1114 and quantize the energy level 1116 of the subbands 1114 into a coarse energy 1120 and a fine energy 1122 (which may represent one or more quantized fine residuals). This disclosure will describe the quantization process for one subband, but it should be understood that the energy quantizer 1106 may perform energy quantization on one or more of the subbands 1114, including each of the subbands 1114.

In general, the energy quantizer 1106 may perform a recursive two-step quantization process. Energy quantizer 1106 may first quantize the energy level 1116 with a first number of bits for a coarse quantization process to generate the coarse energy 1120. The energy quantizer 1106 may generate the coarse energy using a predetermined range of energy levels for the quantization (e.g., the range defined by a maximum and a minimum energy level. The coarse energy 1120 approximates the value of the energy level 1116.

The energy quantizer 1106 may then determine a difference between the coarse energy 1120 and the energy level 1116. This difference is sometimes called a quantization error. The energy quantizer 1106 may then quantize the quantization error using a second number of bits in a fine quantization process to produce the fine energy 1122. The number of bits used for the fine quantization bits is determined by the total number of energy-assigned bits minus the number of bits used for the coarse quantization process. When added together, the coarse energy 1120 and the fine energy 1122 represent a total quantized value of the energy level 1116. The energy quantizer 1106 may continue in this manner to produce one or more fine energies 1122.

The audio encoder 1000A may be further configured to encode the coarse energy 1120, the fine energy 1122, and the residual ID 1124 using a bitstream encoder 1110 to create the encoded audio data 21 (which is another way to refer to the bitstream 21). The bitstream encoder 1110 may be configured to further compress the coarse energy 1120, the fine energy 1122, and the residual ID 1124 using one or more entropy encoding processes. Entropy encoding processes may include Huffman coding, arithmetic coding, context-adaptive binary arithmetic coding (CABAC), and other similar encoding techniques.

In one example of the disclosure, the quantization performed by the energy quantizer 1106 is a uniform quantization. That is, the step sizes (also called “resolution”) of each quantization are equal. In some examples, the steps sizes may be in units of decibels (dBs). The step size for the coarse quantization and the fine quantization may be determined, respectively, from a predetermined range of energy values for the quantization and the number of bits allocated for the quantization. In one example, the energy quantizer 1106 performs uniform quantization for both coarse quantization (e.g., to produce the coarse energy 1120) and fine quantization (e.g., to produce the fine energy 1122).

Performing a two-step, uniform quantization process is equivalent to performing a single uniform quantization process. However, by splitting the uniform quantization into two parts, the bits allocated to coarse quantization and fine quantization may be independently controlled. This may allow for more flexibility in the allocation of bits across energy and vector quantization and may improve compression efficiency. Consider an M-level uniform quantizer, where M defines the number of levels (e.g., in dB) into which the energy level may be divided. M may be determined by the number of bits allocated for the quantization. For example, the energy quantizer 1106 may use M1 levels for coarse quantization and M2 levels for fine quantization. This equivalent to a single uniform quantizer using M1*M2 levels.

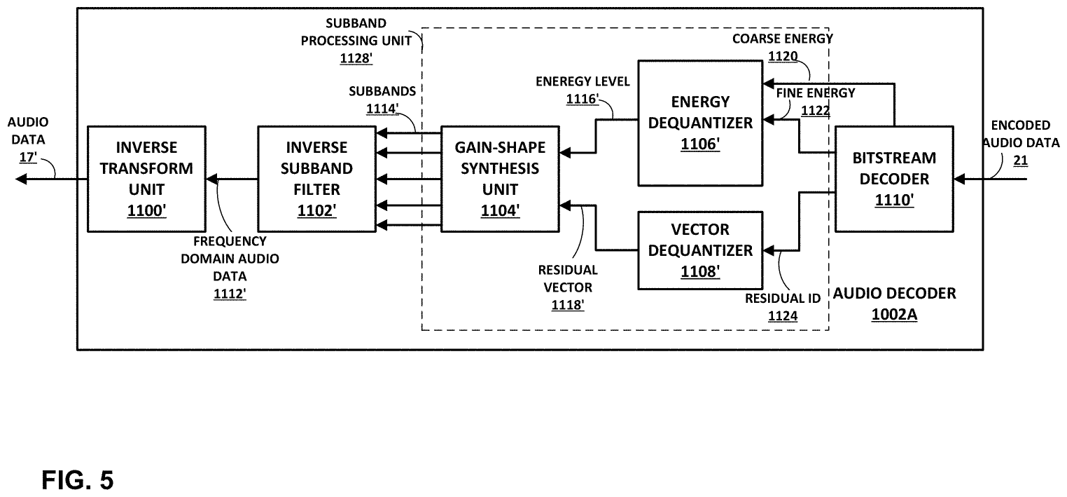

FIG. 5 is a block diagram illustrating an implementation of the psychoacoustic audio decoder of FIGS. 3A-3D in more detail. The audio decoder 1002A may represent one example of an AptX decoder, which may be configured to decode audio data received over a PAN (e.g., Bluetooth®). However, the techniques of this disclosure performed by the audio decoder 1002A may be used in any context where the compression of audio data is desired. In some examples, the audio decoder 1002A may be configured to decode the audio data 21 in accordance with as aptX™ audio codec, including, e.g., enhanced aptX—E-aptX, aptX live, and aptX high definition. However, the techniques of this disclosure may be used in any audio codec configured to perform quantization of audio data. The audio decoder 1002A may be configured to perform various aspects of a quantization process using compact maps in accordance with techniques of this disclosure.

In general, the audio decoder 1002A may operate in a reciprocal manner with respect to audio encoder 1000A. As such, the same process used in the encoder for quality/bitrate scalable cooperative PVQ can be used in the audio decoder 1002A. The decoding is based on the same principals, with inverse of the operations conducted in the decoder, so that audio data can be reconstructed from the encoded bitstream received from encoder. Each quantizer has an associated dequantizater counterpart. For example, as shown in FIG. 5, inverse transform unit 1100′, inverse subband filter 1102′, gain-shape synthesis unit 1104′, energy dequantizer 1106′, vector dequantizer 1108′, and bitstream decoder 1110′ may be respectively configured to perform inverse operations with respect to transform unit 1100, subband filter 1102, gain-shape analysis unit 1104, energy quantizer 1106, vector quantizer 1108, and bitstream encoder 1110 of FIG. 4.

In particular, the gain-shape synthesis unit 1104′ reconstructs the frequency domain audio data, having the reconstructed residual vectors along with the reconstructed energy levels. The inverse subband filter 1102′ and the inverse transform unit 1100′ output the reconstructed audio data 17′. In examples where the encoding is lossless, the reconstructed audio data 17′ may perfectly match the audio data 17. In examples where the encoding is lossy, the reconstructed audio data 17′ may not perfectly match the audio data 17.

In this way, the audio decoder 1002A represents a device configured to receive an encoded audio bitstream (e.g., encoded audio data 21); decode, from the encoded audio bitstream, a unique identifier for each of a plurality of subbands of audio data (e.g., bitstream decoder 1110′ outputs residual ID 1124); perform inverse pyramid vector quantization (PVQ) using a compact map to reconstruct a residual vector for each subband of the plurality of subbands of the audio data based on the unique identifier for the respective subband of the plurality of subbands of the audio data (e.g., vector dequantizer 1108′ performs the inverse quantization); and reconstruct, based on the residual vectors and energy scalars for each subband, the plurality of subbands of the audio data (e.g., gain-shape synthesis unit 1104′ reconstructs the subbands 1114′).

In this way, FIGS. 3A-3D illustrate various examples of audio playback systems that are configured to present legacy format (e.g., mono, stereo, or ESF audio signals) in conjunction with 3D audio data obtained from HOA-domain audio data, to enable better (in terms of user perception) audio playback for legacy audio playback systems. In this way, the systems of FIGS. 3A-3D may improve the operation of the audio playback systems themselves. It will be appreciated that each of the systems illustrated in FIGS. 3A-3D may represent a distributed system, in which the encoding portions of the legacy and/or extended paths are physically separate from, while being in communication with, the decoding and rendering components of the legacy and/or extended paths.

FIG. 9 is a diagram illustrating various aspects of the spatial audio encoding device of FIGS. 2-4 in perform various aspects of the techniques described in this disclosure. In the example of FIG. 9, microphone 5 captures audio signals representative of HOA audio data, which the spatial audio encoder device 20 reduces to a number of different sound components 750A-750N (“sound components 750”) and corresponding spatial components 752A-752N (“spatial components 752”), where the spatial components may generally refer to both the spatial components corresponding to predominant sound components and the corresponding repurposed sound components.

As shown in a table 754, the unified data object format, which may be referred to as a “V-vector based HOA transport format” (VHTF) or “vector based HOA transport format” in the case bitstreams, may include an audio object (which again is another way to refer to a sound component), and a corresponding spatial component (which may be referred to as a “vector”). The audio object (shown as “audio” in the example of FIG. 9) may be denoted by the variable Aᵢ, where i denotes the i-th audio object. The vector (shown as “V-vector” in the example of FIG. 9) is denoted by the variable Vᵢ, where i denotes the i-th vector. Aᵢ is an L×1 column matrix (with L being the number of samples in the frame), and Vᵢ is a M×1 column matrix (with M being the number of elements in the vector).

The reconstructed HOA coefficients 11 may be denoted as \tilde{H}. The reconstructed HOA coefficients 11′ may be determined according to the following equation:

$$\tilde{H} = {\sum }_{i = 0}^{N - 1} {A}_{i} {V}_{i}^{T}$$

According to the above equation, N denotes a total number of sound components in the selected non-zero subset of the plurality of spatial components. The reconstructed HOA coefficients 11′ (\tilde{H}) may be determined as a summation of each iterative (up to N−1 starting at zero) multiplication the audio object (Aᵢ) by the transpose of the vector (Vᵢ^{T}). The spatial audio encoding device 20 may specify the bitstream 15 as shown at the bottom of FIG. 9, where the audio objects 750 are specified along with corresponding spatial components 752 in each frame (denoted by T=1 for the first frame, T=2 for the second frame, etc.).

FIGS. 10A-10C are diagrams illustrating different representations within the bitstream according to various aspects of the unified data object format techniques described in this disclosure. In the example of FIG. 10A, the HOA coefficients 11 are shown as “input”, which the spatial audio encoding device 20 shown in the example of FIG. 2 may transform into a VHTF representation 800 as described above. The VHTF representation 800 in the example of FIG. 10A represents the predominant sound (or foreground—FG—sound) representation. The table 754 is further shown to illustrate the VHTF representation 800 in more detail. In the example of FIG. 8A, there is also spatial representations 802 of the different V-vectors to illustrate how the spatial component defines shape, widths, and directions of the corresponding spatial component.

In the example of FIG. 10B, the HOA coefficients 11 are shown as “input”, which the spatial audio encoding device 20 shown in the example of FIG. 2 may transform into a VHTF representation 806 as described above. The VHTF representation 806 in the example of FIG. 8B represents the ambient sound (or background—BG—sound) representation. The table 754 is further shown to illustrate the VHTF representation 806 in more detail, where both the VHTF representation 800 and the VHTF representation 806 have the same format. In the example of FIG. 10B, there is also examples 808 of the different repurposed V-vectors to illustrate how the repurposed V-vectors may include a single element with a value of one with every other element being set to a value of zero so as to, as described above, identify the order and sub-order of the spherical basis function to which the ambient HOA coefficient corresponds.

In the example of FIG. 10C, the HOA coefficients 11 are shown as “input”, which the spatial audio encoding device 20 shown in the example of FIG. 2 may transform into a VHTF representation 810 as described above. The VHTF representation 810 in the example of FIG. 8C represents the sound components, but also includes the priority information 812 (shown as “PriorityOfTC,” which refers to a priority of transport channels). The table 754 is updated in FIG. 10C to further illustrate the VHTF representation 810 in more detail, where both the VHTF representation 800 and the VHTF representation 806 have the same format and VHTF representation 810 includes the priority information 812.

In each instance, the spatial audio encoding device 20 may specify the unified transport type (or, in other words, the VHTF) by setting the HoaTransportType syntax element in the following table to 3.

| | No. of | |
|---|---|---|
| Syntax | bits | Mnemonic |
| HOATransportConfig( ) | | |
| { | | |
| HoaTransportType; | 3 | uimsbf |
| if (HoaTransportType == 0) { | | |
| InputSamplingFrequency; | 3 | uimsbf |
| HoaOrder; | 3 | uimsbf |
| NumOfHoaCoeffs = ( HoaOrder + 1 )\hat{ }2; | | |
| HoaNormalization; | 2 | uimsbf |
| HoaCoeffOrdering; | 2 | uimsbf |
| IsScreenRelative; | 1 | bslbf |
| if (IsScreenRelative) { | | |
| hasNonStandardScreenSize; | 1 | bslbf |
| if (hasNonStandardScreenSize) { | | |
| bsScreenSizeAz; | 9 | uimsbf |
| bsScreenSizeTopEl; | 9 | uimsbf |
| bsScreenSizeBottomEl; | 9 | uimsbf |
| } | | |
| } | | |
| } else if (HoaTransportType == 1) { | | |
| HoaNormalization = 1; | | |
| HoaCoeffOrdering = 0; | | |
| HOAConfig( ); | | |
| } else if (HoaTransportType == 2) { | | |
| HoaNormalization = 0; | | |
| HoaCoeffOrdering = 0; | | |
| HOAConfig_SN3D( ); | | |
| } else if (HoaTransportType == 3) { | | |
| InputSamplingFrequency; | 3 | uimsbf |
| HoaFrameLength; | 3 | uimsbf |
| HoaOrder; | 3 | uimsbf |
| NumOfHoaCoeffs = ( HoaOrder + 1 )\hat{ }2; | | |
| HoaNormalization = 0; | | |
| HoaCoeffOrdering = 0; | | |
| IsScreenRelative; | 1 | bslbf |
| if (IsScreenRelative) { | | |
| hasNonStandardScreenSize; | 1 | bslbf |
| if (hasNonStandardScreenSize) { | | |
| bsScreenSizeAz; | 9 | uimsbf |
| bsScreenSizeTopEl; | 9 | uimsbf |
| bsScreenSizeBottomEl; | 9 | uimsbf |
| } | | |
| } | | |
| NumOfTransportChannels = | | |
| | 4 | uimsbf |
| CodedNumOfTransportChannels + 1; | | |
| } | | |
| } | | |

As noted in the below table, the HoaTransportType indicates the HOA transport mode, and when set to a value of three (3) signals that the transport type is VHTF.

| | |
|---|---|
| HoaTransportType | This element contains information about |
| | HOA transport mode. |
| | 0: HOA coefficients (as defined in |
| | this clause) |
| | 1: ISO/IEC 23008-3-based HOA |
| | Transport Format |
| | 2: Modified ISO/IEC 23008-3- |
| | based HOA Transport Format for SN3D |
| | normalization |
| | 3: V-vector based HOA Transport |
| | Format (VHTF) as defined below |
| | 4-7: reserved |

Regarding the VHTF (HoaTransportType=3), FIGS. 9 and 10A-10C may illustrate how VHTF is composed of audio signals, {Aᵢ}, and the associated V-vectors, {Vᵢ}, where an input HOA signal, H, can be approximated by

$$\tilde{H} = {\sum }_{i = 0}^{N - 1} {A}_{i} {V}_{i}^{T}$$

where an i-th V-vector, Vᵢ, is the spatial representation of the i-th audio signal, Aᵢ. N is the number of transport channels. The dynamic range of each Vᵢ is bound by [−1, 1]. Examples of V-vector based spatial representation 802 are shown in FIG. 8A.
VHTF can also represent an original input HOA, which means \tilde{H}=H, in the following conditions:
if Vᵢ has all zero elements but one at an i-th element [0 0 . . . 1 . . . 0]^{T}
and if Aᵢ is the i-th HOA coefficients.

Thus, VHTF can represent both pre-dominant and ambient sound fields.

As shown in Table 15, the HOAFrame_VvecTransportFormat( ) holds the information that is required to decode the L samples (HoaFrameLength in Table 1) of an HOA frame.

Syntax of HOAFrame_VvecTransportFormat( )

| | No. of | |
|---|---|---|
| Syntax | bits | Mnemonic |
| HOAFrame_VvecTransportFormat( ) | | |
| { | | uimsbf |
| VvectorBits = | 3 | |
| codedVvectorBitDepth*2+1; | | |
| PriorityBits = | | uimsbf |
| ceil(log2(NumOfTransportChannels)); | PriorityBits | |
| for | | uimsbf |
| (i=0;i<NumOfTransportChannels;i++) { | | |
| priorityOfTC[i]; | VvectorBits | |
| for (j=0;j<NumOfHoaCoeffs; j++) { | | |
| Vvector[i][j]; | | |
| } | | |
| } | | |
| } | | |
| } | | |

| | |
|---|---|
| NumOfTransportChannels | This element contains information about the |
| | number of transport channels defined in |
| | Table 1. |
| codedVvectorBitDepth | This element contains information about the |
| | coded bit depth of a V-vector. |
| NumOfHoaCoeffs | This element contains information about the |
| | number of HOA coefficients defined in |
| | Table 1. |
| VvectorBits | This element contains information about the |
| | bit depth of a V-vector. |
| PriorityBits | This element contains information about the |
| | bit depth of HOA transport channel priority. |
| priorityOfTC[i] | This element contains information about the |
| | priority of an i-th transport channel (the |
| | channel with a lower priority value is more |
| | important, thus the channel with |
| | priorityOfTC[i] = 0 is the channel with the |
| | highest priority). |
| Vvector[i][j] | This element contains information about a |
| | vector element representing spatial |
| | information. Its value is bounded by [−1,1]. |

In the foregoing syntax tables, Vvector[i][j] refers to the spatial component, where i identifies which transport channel, and j identifies which coefficient (by way of the order and sub-order of the spherical basis function to which the ambient HOA coefficient corresponds in the case when Vvector represents the repurposed spatial component).

The audio decoding device 24 (shown in the example of FIG. 2) may receive the bitstream 21 and obtain the HoaTransportType syntax element from the bitstream 21. Based on the HoaTransportType syntax element, the audio decoding device 24 may extract the various sound components and corresponding spatial components to render the speaker feeds in the manner described above in more detail.

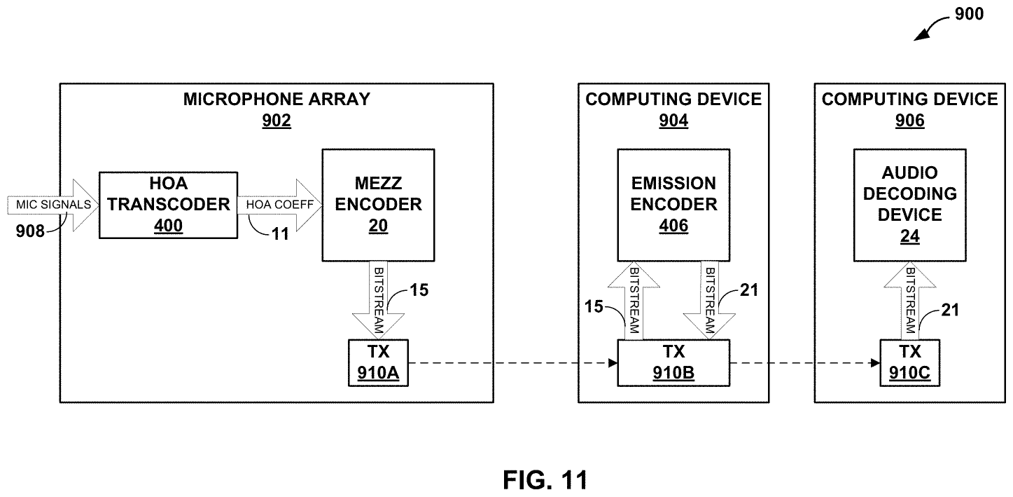

FIG. 11 is a block diagram illustrating a different system configured to perform various aspects of the techniques described in this disclosure. In the example of FIG. 11, a system 900 includes a microphone array 902 and computing devices 904 and 906. The microphone array 902 may be similar, if not substantially similar, to the microphone array 5 described above with respect to the example of FIG. 2. The microphone array 902 includes the HOA transcoder 400 and the mezzanine encoder 20 discussed in more detail above.

The computing devices 904 and 906 may each represent one or more of a cellular phone (which may be interchangeably be referred to as a “mobile phone,” or “mobile cellular handset” and where such cellular phone may including so-called “smart phones”), a tablet, a laptop, a personal digital assistant, a wearable computing headset, a watch (including a so-called “smart watch”), a gaming console, a portable gaming console, a desktop computer, a workstation, a server, or any other type of computing device. For purposes of illustration, each of the computing devices 904 and 906 is referred to a respective mobile phone 904 and 906. In any event, the mobile phone 904 may include the emission encoder 406, while the mobile phone 906 may include the audio decoding device 24.

The microphone array 902 may capture audio data in the form of microphone signals 908. The HOA transcoder 400 of the microphone array 902 may transcode the microphone signals 908 into the HOA coefficients 11, which the mezzanine encoder 20 (shown as “mezz encoder 20”) may encode (or, in other words, compress) to form the bitstream 15 in the manner described above. The microphone array 902 may be coupled (either wirelessly or via a wired connection) to the mobile phone 904 such that the microphone array 902 may communicate the bitstream 15 via a transmitter and/or receiver (which may also be referred to as a transceiver, and abbreviated as “TX”) 910A to the emission encoder 406 of the mobile phone 904. The microphone array 902 may include the transceiver 910A, which may represent hardware or a combination of hardware and software (such as firmware) configured to transmit data to another transceiver.

The emission encoder 406 may operate in the manner described above to generate the bitstream 21 conforming to the 3D Audio Coding Standard from the bitstream 15. The emission encoder 406 may include a transceiver 910B (which is similar to if not substantially similar to transceiver 910A) configured to receive the bitstream 15. The emission encoder 406 may select the target bitrate, hoaIndependencyFlag syntax element, and the number of transport channels when generating the bitstream 21 from the received bitstream 15 (selecting the number of transport channels as the subset of transport channels according to the priority information). The emission encoder 406 may communicate (although not necessarily directly, meaning that such communication may have intervening devices, such as servers, or by way of dedicated non-transitory storage media, etc.) the bitstream 21 via the transceiver 910B to the mobile phone 906.

The mobile phone 906 may include transceiver 910C (which is similar to if not substantially similar to transceivers 910A and 910B) configured to receive the bitstream 21, whereupon the mobile phone 906 may invoke audio decoding device 24 to decode the bitstream 21 so as to recover the HOA coefficients 11′. Although not shown in FIG. 10 for ease of illustration purposes, the mobile phone 906 may render the HOA coefficients 11′ to speaker feeds, and reproduce the soundfield via a speaker (e.g., a loudspeaker integrated into the mobile phone 906, a loudspeaker wirelessly coupled to the mobile phone 906, a loudspeaker coupled by wire to the mobile phone 906, or a headphone speaker coupled either wirelessly or via wired connection to the mobile phone 906) based on the speaker feeds. For reproducing the soundfield by way of headphone speakers (which again may be standalone headphones or headphones integrated into a headset), the mobile phone 906 may render binaural audio speaker feeds from either the loudspeaker feeds or directly from the HOA coefficients 11′.

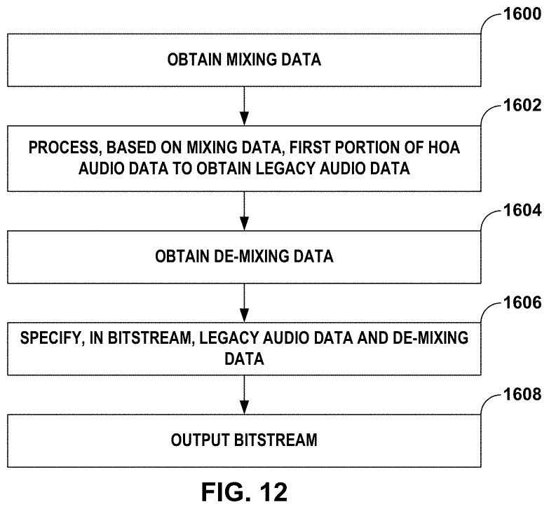

FIG. 12 is a flowchart illustrating example operation of the broadcast network center of FIG. 1 in performing various aspects of the techniques described in this disclosure. The mixing unit 404 of the broadcast network center 402 may obtain mixing data that indicates how to process a first portion of the HOA audio data to obtain legacy audio data (1600). The mixing unit 404 may next process, based on the mixing data, a first portion of the HOA audio data to obtain the legacy audio data 25B (1602). The broadcast network center 402 may then obtain de-mixing data (e.g., the parameters 403) that indicates how to process the legacy audio data 25B to obtain the first portion of the HOA audio data (1604). Next, the broadcast network center 402 may specify, in the bitstream 17 that includes a second portion of the HOA audio data, the legacy audio data 25B and the de-mixing data (1606). The broadcast network center 402 may output the bitstream (1608).

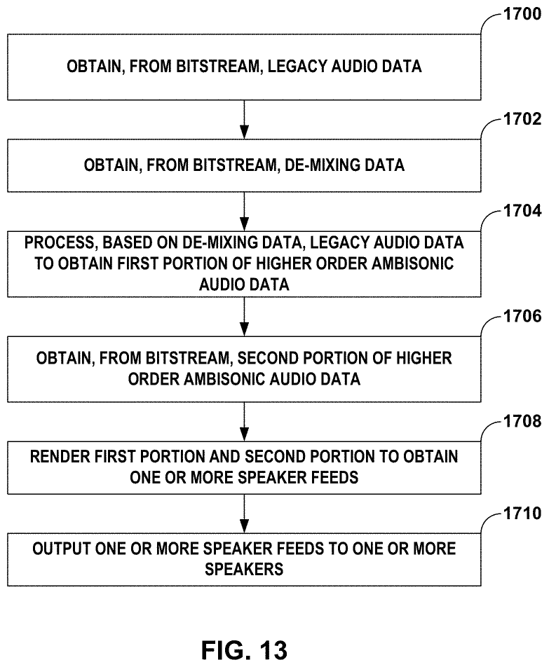

FIG. 13 is a flowchart illustrating example operation of the audio playback device of FIG. 1 in performing various aspects of the techniques described in this disclosure. The audio decoding device 24 may first obtain the bitstream 21 and perform psychoacoustic audio decoding with respect to the bitstream 21 to obtain the bitstream 17. The audio decoding device 24 may obtain, from the backward compatible bitstream 17 that conforms to a legacy transport format, the legacy audio data 25B that conforms to the legacy audio format (1700).

The audio decoding device 24 may next obtain, from the backward compatible bitstream 17, de-mixing data that indicates how to process the legacy audio data 25B to obtain a first portion of the HOA audio data 11′ (1702). The audio decoding device 24 may process, based on the de-mixing data, the legacy audio data 25B to obtain the first portion of the HOA audio data (1704). Next, the audio decoding device 24 may obtain, from the bitstream 21, a second portion of the HOA audio data 11′ (1706). The audio decoding device 24 may output the first and second portions of the HOA audio data 11′ to a renderer 22. The renderer 22 may render the first portion and the second portion of the HOA audio data 11′ to obtain one or more speaker feeds 25A (1708). The renderer 22 may output the one or more speaker feeds 25A to one or more speakers 3 to reproduce a soundfield represented by the HOA audio data 11′ (1710).

In addition, the foregoing techniques may be performed with respect to any number of different contexts and audio ecosystems and should not be limited to any of the contexts or audio ecosystems described above. A number of example contexts are described below, although the techniques should be limited to the example contexts. One example audio ecosystem may include audio content, movie studios, music studios, gaming audio studios, channel based audio content, coding engines, game audio stems, game audio coding/rendering engines, and delivery systems.

The movie studios, the music studios, and the gaming audio studios may receive audio content. In some examples, the audio content may represent the output of an acquisition. The movie studios may output channel based audio content (e.g., in 2.0, 5.1, and 7.1) such as by using a digital audio workstation (DAW). The music studios may output channel based audio content (e.g., in 2.0, and 5.1) such as by using a DAW. In either case, the coding engines may receive and encode the channel based audio content based one or more codecs (e.g., AAC, AC3, Dolby True HD, Dolby Digital Plus, and DTS Master Audio) for output by the delivery systems. The gaming audio studios may output one or more game audio stems, such as by using a DAW. The game audio coding/rendering engines may code and or render the audio stems into channel based audio content for output by the delivery systems. Another example context in which the techniques may be performed comprises an audio ecosystem that may include broadcast recording audio objects, professional audio systems, consumer on-device capture, HOA audio format, on-device rendering, consumer audio, TV, and accessories, and car audio systems.

The broadcast recording audio objects, the professional audio systems, and the consumer on-device capture may all code their output using HOA audio format. In this way, the audio content may be coded using the HOA audio format into a single representation that may be played back using the on-device rendering, the consumer audio, TV, and accessories, and the car audio systems. In other words, the single representation of the audio content may be played back at a generic audio playback system (i.e., as opposed to requiring a particular configuration such as 5.1, 7.1, etc.), such as audio playback system 16.

Other examples of context in which the techniques may be performed include an audio ecosystem that may include acquisition elements, and playback elements. The acquisition elements may include wired and/or wireless acquisition devices (e.g., Eigen microphones), on-device surround sound capture, and mobile devices (e.g., smartphones and tablets). In some examples, wired and/or wireless acquisition devices may be coupled to mobile device via wired and/or wireless communication channel(s).

In accordance with one or more techniques of this disclosure, the mobile device (such as a mobile communication handset) may be used to acquire a soundfield. For instance, the mobile device may acquire a soundfield via the wired and/or wireless acquisition devices and/or the on-device surround sound capture (e.g., a plurality of microphones integrated into the mobile device). The mobile device may then code the acquired soundfield into the HOA coefficients for playback by one or more of the playback elements. For instance, a user of the mobile device may record (acquire a soundfield of) a live event (e.g., a meeting, a conference, a play, a concert, etc.), and code the recording into HOA coefficients.

The mobile device may also utilize one or more of the playback elements to playback the HOA coded soundfield. For instance, the mobile device may decode the HOA coded soundfield and output a signal to one or more of the playback elements that causes the one or more of the playback elements to recreate the soundfield. As one example, the mobile device may utilize the wireless and/or wireless communication channels to output the signal to one or more speakers (e.g., speaker arrays, sound bars, etc.). As another example, the mobile device may utilize docking solutions to output the signal to one or more docking stations and/or one or more docked speakers (e.g., sound systems in smart cars and/or homes). As another example, the mobile device may utilize headphone rendering to output the signal to a set of headphones, e.g., to create realistic binaural sound.

In some examples, a particular mobile device may both acquire a 3D soundfield and playback the same 3D soundfield at a later time. In some examples, the mobile device may acquire a 3D soundfield, encode the 3D soundfield into HOA, and transmit the encoded 3D soundfield to one or more other devices (e.g., other mobile devices and/or other non-mobile devices) for playback.

Yet another context in which the techniques may be performed includes an audio ecosystem that may include audio content, game studios, coded audio content, rendering engines, and delivery systems. In some examples, the game studios may include one or more DAWs which may support editing of HOA signals. For instance, the one or more DAWs may include HOA plugins and/or tools which may be configured to operate with (e.g., work with) one or more game audio systems. In some examples, the game studios may output new stem formats that support HOA. In any case, the game studios may output coded audio content to the rendering engines which may render a soundfield for playback by the delivery systems.

The techniques may also be performed with respect to exemplary audio acquisition devices. For example, the techniques may be performed with respect to an Eigen microphone which may include a plurality of microphones that are collectively configured to record a 3D soundfield. In some examples, the plurality of microphones of an Eigen microphone may be located on the surface of a substantially spherical ball with a radius of approximately 4 cm. In some examples, the audio encoding device 20 may be integrated into the Eigen microphone so as to output a bitstream 21 directly from the microphone.

Another exemplary audio acquisition context may include a production truck which may be configured to receive a signal from one or more microphones, such as one or more Eigen microphones. The production truck may also include an audio encoder, such as audio encoder 20 of FIG. 5.

The mobile device may also, in some instances, include a plurality of microphones that are collectively configured to record a 3D soundfield. In other words, the plurality of microphones may have X, Y, Z diversity. In some examples, the mobile device may include a microphone which may be rotated to provide X, Y, Z diversity with respect to one or more other microphones of the mobile device. The mobile device may also include an audio encoder, such as audio encoder 20 of FIG. 5.

A ruggedized video capture device may further be configured to record a 3D soundfield. In some examples, the ruggedized video capture device may be attached to a helmet of a user engaged in an activity. For instance, the ruggedized video capture device may be attached to a helmet of a user whitewater rafting. In this way, the ruggedized video capture device may capture a 3D soundfield that represents the action all around the user (e.g., water crashing behind the user, another rafter speaking in front of the user, etc. . . . ).

The techniques may also be performed with respect to an accessory enhanced mobile device, which may be configured to record a 3D soundfield. In some examples, the mobile device may be similar to the mobile devices discussed above, with the addition of one or more accessories. For instance, an Eigen microphone may be attached to the above noted mobile device to form an accessory enhanced mobile device. In this way, the accessory enhanced mobile device may capture a higher quality version of the 3D soundfield than just using sound capture components integral to the accessory enhanced mobile device.

Example audio playback devices that may perform various aspects of the techniques described in this disclosure are further discussed below. In accordance with one or more techniques of this disclosure, speakers and/or sound bars may be arranged in any arbitrary configuration while still playing back a 3D soundfield. Moreover, in some examples, headphone playback devices may be coupled to a decoder 24 via either a wired or a wireless connection. In accordance with one or more techniques of this disclosure, a single generic representation of a soundfield may be utilized to render the soundfield on any combination of the speakers, the sound bars, and the headphone playback devices.

A number of different example audio playback environments may also be suitable for performing various aspects of the techniques described in this disclosure. For instance, a 5.1 speaker playback environment, a 2.0 (e.g., stereo) speaker playback environment, a 9.1 speaker playback environment with full height front loudspeakers, a 22.2 speaker playback environment, a 16.0 speaker playback environment, an automotive speaker playback environment, and a mobile device with ear bud playback environment may be suitable environments for performing various aspects of the techniques described in this disclosure.

In accordance with one or more techniques of this disclosure, a single generic representation of a soundfield may be utilized to render the soundfield on any of the foregoing playback environments. Additionally, the techniques of this disclosure enable a rendered to render a soundfield from a generic representation for playback on the playback environments other than that described above. For instance, if design considerations prohibit proper placement of speakers according to a 7.1 speaker playback environment (e.g., if it is not possible to place a right surround speaker), the techniques of this disclosure enable a render to compensate with the other 6 speakers such that playback may be achieved on a 6.1 speaker playback environment.

Moreover, a user may watch a sports game while wearing headphones. In accordance with one or more techniques of this disclosure, the 3D soundfield of the sports game may be acquired (e.g., one or more Eigen microphones may be placed in and/or around the baseball stadium), HOA coefficients corresponding to the 3D soundfield may be obtained and transmitted to a decoder, the decoder may reconstruct the 3D soundfield based on the HOA coefficients and output the reconstructed 3D soundfield to a renderer, and the renderer may obtain an indication as to the type of playback environment (e.g., headphones), and render the reconstructed 3D soundfield into signals that cause the headphones to output a representation of the 3D soundfield of the sports game.

In each of the various instances described above, it should be understood that the audio encoding device 20 may perform a method or otherwise comprise means to perform each step of the method for which the audio encoding device 20 is configured to perform In some instances, the means may comprise one or more processors, e.g., formed by fixed-function processing circuitry, programmable processing circuitry or a combination thereof. In some instances, the one or more processors (which may be denoted as “processor(s)”) may represent a special purpose processor configured by way of instructions stored to a non-transitory computer-readable storage medium. In other words, various aspects of the techniques in each of the sets of encoding examples may provide for a non-transitory computer-readable storage medium having stored thereon instructions that, when executed, cause the one or more processors to perform the method for which the audio encoding device 20 has been configured to perform.

In one or more examples, the functions described may be implemented in hardware, software, firmware, or any combination thereof. If implemented in software, the functions may be stored on or transmitted over as one or more instructions or code on a computer-readable medium and executed by a hardware-based processing unit. Computer-readable media may include computer-readable storage media, which corresponds to a tangible medium such as data storage media. Data storage media may be any available media that can be accessed by one or more computers or one or more processors to retrieve instructions, code and/or data structures for implementation of the techniques described in this disclosure. A computer program product may include a computer-readable medium.

Likewise, in each of the various instances described above, it should be understood that the audio decoding device 24 may perform a method or otherwise comprise means to perform each step of the method for which the audio decoding device 24 is configured to perform. In some instances, the means may comprise one or more processors, e.g., formed by fixed-function processing circuitry, programmable processing circuitry or a combination thereof. In some instances, the one or more processors may represent a special purpose processor configured by way of instructions stored to a non-transitory computer-readable storage medium. In other words, various aspects of the techniques in each of the sets of encoding examples may provide for a non-transitory computer-readable storage medium having stored thereon instructions that, when executed, cause the one or more processors to perform the method for which the audio decoding device 24 has been configured to perform.

By way of example, and not limitation, such computer-readable storage media can comprise RAM, ROM, EEPROM, CD-ROM or other optical disk storage, magnetic disk storage, or other magnetic storage devices, flash memory, or any other medium that can be used to store desired program code in the form of instructions or data structures and that can be accessed by a computer. It should be understood, however, that computer-readable storage media and data storage media do not include connections, carrier waves, signals, or other transitory media, but are instead directed to non-transitory, tangible storage media. Disk and disc, as used herein, includes compact disc (CD), laser disc, optical disc, digital versatile disc (DVD), floppy disk and Blu-ray disc, where disks usually reproduce data magnetically, while discs reproduce data optically with lasers. Combinations of the above should also be included within the scope of computer-readable media.

Instructions may be executed by one or more processors, such as one or more digital signal processors (DSPs), general purpose microprocessors, application specific integrated circuits (ASICs), field programmable gate arrays (FPGAs), processing circuitry (including fixed function circuitry and/or programmable processing circuitry), or other equivalent integrated or discrete logic circuitry. Accordingly, the term “processor,” as used herein may refer to any of the foregoing structure or any other structure suitable for implementation of the techniques described herein. In addition, in some aspects, the functionality described herein may be provided within dedicated hardware and/or software modules configured for encoding and decoding, or incorporated in a combined codec. Also, the techniques could be fully implemented in one or more circuits or logic elements.

The techniques of this disclosure may be implemented in a wide variety of devices or apparatuses, including a wireless handset, an integrated circuit (IC) or a set of ICs (e.g., a chip set). Various components, modules, or units are described in this disclosure to emphasize functional aspects of devices configured to perform the disclosed techniques, but do not necessarily require realization by different hardware units. Rather, as described above, various units may be combined in a codec hardware unit or provided by a collection of interoperative hardware units, including one or more processors as described above, in conjunction with suitable software and/or firmware.

As such, various aspects of the techniques may enable one or more devices to operate in accordance with the following clauses.

Clause 31C. A device configured to process a bitstream representative of higher order ambisonic audio data, the device comprising: means for obtaining, from the bitstream, legacy audio data that conforms to a legacy audio form; means for obtaining, from the bitstream, de-mixing data that indicates how to process the legacy audio data to obtain a first portion of the higher order ambisonic audio data; means for processing, based on the de-mixing data, the legacy audio data to obtain a first portion of the higher order ambisonic audio data; means for obtaining, from the bitstream, a second portion of the higher order ambisonic audio data; means for rendering the first portion of the higher order ambisonic audio data and the second portion of the higher order ambisonic audio data to obtain one or more speaker feeds; and means for outputting the one or more speaker feeds to one or more speakers.

Clause 32C. The device of clause 31C, wherein the means for processing the legacy audio data comprises means for de-mixing, based on the de-mix data, the legacy audio data to obtain the first portion of the higher order ambisonic audio data.

Clause 33C. The device of any combination of clauses 31C and 32C, wherein the de-mix data includes de-mix data representative of a de-mix matrix.

Clause 34C. The device of any combination of clauses 31C-33C, wherein the de-mix data includes de-mix data representative of a de-mix matrix that converts N input signals into M output signals, and wherein N does not equal M.

Clause 35C. The device of any combination of clauses 33C and 34C, wherein the de-mix data includes sparseness information indicative of a sparseness of the de-mix matrix.

Clause 36C. The device of any combination of clauses 33C-35C, wherein the de-mix data includes symmetry information that indicates a symmetry of the de-mix matrix.

Clause 37C. The device of clause 36C, wherein the symmetry information includes value symmetry information that indicates value symmetry of the de-mix matrix.

Clause 38C. The device of any combination of clauses 36C and 37C, wherein the symmetry information includes sign symmetry information that indicates sign symmetry of the de-mix matrix.

Clause 39C. The device of any combination of clauses 31C-38C, wherein the first portion of the higher order ambisonic audio data comprises ambient higher order ambisonic audio data.

Clause 40C. The device of clause 39C, wherein the one or more speakers include two speakers that provide stereo audio playback, and wherein the legacy audio data includes stereo audio data that conforms to the stereo audio format, and includes a left channel and a right channel.

Clause 41C. The device of clause 39C, wherein the one or more speakers include five speakers that provide surround sound audio playback, and wherein the legacy audio data includes surround sound audio data that conforms to the 5.1 channel audio format, and includes a left channel, a right channel, a center channel, a back left channel, and a back right channel.

Clause 42C. The device of any combination of clauses 31C-41C, wherein the second portion of the higher order ambisonic audio data includes one or more coefficients corresponding to spherical basis functions to which one or more coefficients of the first portion of the higher order ambisonic audio data do not correspond.

Clause 43C. The device of any combination of clauses 31A-41C, wherein the first portion of the higher order ambisonic audio data comprises a first coefficient corresponding to a zero-order spherical basis function.

Clause 44C. The device of any combination of clauses 31C-41C, wherein the first portion of the higher order ambisonic audio data comprises a first coefficient corresponding to a zero-order spherical basis function, and a second coefficient corresponding to a first-order spherical basis function.

Clause 45C. The device of any combination of clauses 31C-41C, wherein the first portion of the higher order ambisonic audio data comprises a first coefficient corresponding to a zero-order spherical basis function, a second coefficient corresponding to a first-order, zero-sub-order spherical basis function, a third coefficient corresponding to a first-order negative-one-sub-order spherical basis function, and a fourth coefficient corresponding to a first-order, first-sub-order spherical basis function.

Clause 46C. A non-transitory computer-readable storage medium having stored thereon instructions that, when executed, cause one or more processors to: obtain, from a bitstream representative of higher order ambisonic audio data, legacy audio data that conforms to a legacy audio format; obtain, from the bitstream, de-mixing data that indicates how to process the legacy audio data to obtain a first portion of the higher order ambisonic audio data; process, based on the de-mixing data, the legacy audio data to obtain the first portion of the higher order ambisonic audio data; obtain, from the bitstream, a second portion of the higher order ambisonic audio data; render the first portion of the higher order ambisonic audio data and the second portion of the higher order ambisonic audio data to obtain one or more speaker feeds; and output the one or more speaker feeds to one or more speakers to reproduce a soundfield represented by the higher order ambisonic audio data.

Clause 1D. A device configured to obtain a bitstream representative of higher order ambisonic audio data, the device comprising: one or more memories configured to store the higher order ambisonic audio data; and one or more processors configured to: obtain mixing data that indicates how to process a first portion of the higher order ambisonic audio data to obtain legacy audio data; process, based on the mixing data, the first portion of the higher order ambisonic audio data to obtain the legacy audio data; obtain de-mixing data that indicates how to process the legacy audio data to obtain the first portion of the higher order ambisonic audio data; specify, in the bitstream that includes a second portion of the higher order ambisonic audio data, the legacy audio data and the de-mixing data; and output the bitstream.

Clause 2D. The device of clause 1D, wherein the de-mix data includes de-mix data representative of a de-mix matrix.

Clause 3D. The device of any combination of clauses 1D and 2D, wherein the de-mix data includes de-mix data representative of a de-mix matrix that converts N input signals into M output signals, and wherein N does not equal M.

Clause 4D. The device of any combination of clauses 2D and 3D, wherein the de-mix data includes sparseness information indicative of a sparseness of the de-mix matrix.

Clause 5D. The device of any combination of clauses 2D-4D, wherein the de-mix data includes symmetry information that indicates a symmetry of the de-mix matrix.

Clause 6D. The device of clause 5D, wherein the symmetry information includes value symmetry information that indicates value symmetry of the de-mix matrix.

Clause 7D. The device of any combination of clauses 5D and 6D, wherein the symmetry information includes sign symmetry information that indicates sign symmetry of the de-mix matrix.

Clause 8D. The device of any combination of clauses 1D-7D, wherein the one or more processors are configured to interface with one or more microphones that captures audio data representative of the higher order ambisonic audio data.

Clause 9D. The device of any combination of clauses 1D-8D, wherein the legacy audio data includes stereo audio data that conforms to the stereo audio format, and includes a left channel and a right channel.

Clause 10D. The device of any combination of clauses 1D-8D, wherein the legacy audio data includes surround sound audio data that conforms to the 5.1 channel audio format, and includes a left channel, a right channel, a center channel, a back left channel, and a back right channel.

Clause 11D. The device of any combination of clauses 1D-10D, wherein the second portion of the higher order ambisonic audio data includes one or more coefficients corresponding to spherical basis functions to which one or more coefficients of the first portion of the higher order ambisonic audio data do not correspond.

Clause 12D. The device of any combination of clauses 1D-10D, wherein the first portion of the higher order ambisonic audio data comprises a first coefficient corresponding to a zero-order spherical basis function.

Clause 13D. The device of any combination of clauses 1D-10D, wherein the first portion of the higher order ambisonic audio data comprises a first coefficient corresponding to a zero-order spherical basis function, and a second coefficient corresponding to a first-order spherical basis function.

Clause 14D. The device of any combination of clauses 1D-10D, wherein the first portion of the higher order ambisonic audio data comprises a first coefficient corresponding to a zero-order spherical basis function, a second coefficient corresponding to a first-order, zero-sub-order spherical basis function, a third coefficient corresponding to a first-order negative-one-sub-order spherical basis function, and a fourth coefficient corresponding to a first-order, first-sub-order spherical basis function.

Clause 15D. A method of obtaining a bitstream representative of higher order ambisonic audio data, the method comprising: obtaining mixing data that indicates how to process a first portion of the higher order ambisonic audio data to obtain legacy audio data; processing, based on the mixing data, the first portion of the higher order ambisonic audio data to obtain the legacy audio data; obtaining de-mixing data that indicates how to process the legacy audio data to obtain the first portion of the higher order ambisonic audio data; specifying, in the bitstream that includes a second portion of the higher order ambisonic audio data, the legacy audio data and the de-mixing data; and outputting the bitstream.

Clause 16D. The method of clause 15D, wherein the de-mix data includes de-mix data representative of a de-mix matrix.

Clause 17D. The method of any combination of clauses 15D and 16D, wherein the de-mix data includes de-mix data representative of a de-mix matrix that converts N input signals into M output signals, and wherein N does not equal M.

Clause 18D. The method of any combination of clauses 16D and 17D, wherein the de-mix data includes sparseness information indicative of a sparseness of the de-mix matrix.

Clause 19D. The method of any combination of clauses 16D-18D, wherein the de-mix data includes symmetry information that indicates a symmetry of the de-mix matrix.

Clause 20D. The method of clause 19D, wherein the symmetry information includes value symmetry information that indicates value symmetry of the de-mix matrix.

Clause 21D. The method of any combination of clauses 19D and 20D, wherein the symmetry information includes sign symmetry information that indicates sign symmetry of the de-mix matrix.

Clause 22D. The method of any combination of clauses 15D-21D, further comprising interfacing with one or more microphones that captures audio data representative of the higher order ambisonic audio data.

Clause 23D. The method of any combination of clauses 15D-22D, wherein the legacy audio data includes stereo audio data that conforms to the stereo audio format, and includes a left channel and a right channel.

Clause 24D. The method of any combination of clauses 15D-22D, wherein the legacy audio data includes surround sound audio data that conforms to the 5.1 channel audio format, and includes a left channel, a right channel, a center channel, a back left channel, and a back right channel.

Clause 25D. The method of any combination of clauses 15D-24D, wherein the second portion of the higher order ambisonic audio data includes one or more coefficients corresponding to spherical basis functions to which one or more coefficients of the first portion of the higher order ambisonic audio data do not correspond.

Clause 26D. The method of any combination of clauses 15D-24D, wherein the first portion of the higher order ambisonic audio data comprises a first coefficient corresponding to a zero-order spherical basis function.

Clause 27D. The method of any combination of clauses 15D-24D, wherein the first portion of the higher order ambisonic audio data comprises a first coefficient corresponding to a zero-order spherical basis function, and a second coefficient corresponding to a first-order spherical basis function.

Clause 28D. The method of any combination of clauses 15D-24D, wherein the first portion of the higher order ambisonic audio data comprises a first coefficient corresponding to a zero-order spherical basis function, a second coefficient corresponding to a first-order, zero-sub-order spherical basis function, a third coefficient corresponding to a first-order negative-one-sub-order spherical basis function, and a fourth coefficient corresponding to a first-order, first-sub-order spherical basis function.

Clause 29D. A device configured to obtain a bitstream representative of higher order ambisonic audio data, the device comprising: means for obtaining mixing data that indicates how to process a first portion of the higher order ambisonic audio data to obtain legacy audio data; means for processing, based on the mixing data, the first portion of the higher order ambisonic audio data to obtain the legacy audio data; means for obtaining de-mixing data that indicates how to process the legacy audio data to obtain the first portion of the higher order ambisonic audio data; means for specifying, in the bitstream that includes a second portion of the higher order ambisonic audio data, the legacy audio data and the de-mixing data; and means for outputting the bitstream.

Clause 30D. The device of clause 29D, wherein the de-mix data includes de-mix data representative of a de-mix matrix.

Clause 31D. The device of any combination of clauses 29D and 30D,

wherein the de-mix data includes de-mix data representative of a de-mix matrix that converts N input signals into M output signals, and wherein N does not equal M.

Clause 32D. The device of any combination of clauses 30D and 31D, wherein the de-mix data includes sparseness information indicative of a sparseness of the de-mix matrix.

Clause 33D. The device of any combination of clauses 30D-32D, wherein the de-mix data includes symmetry information that indicates a symmetry of the de-mix matrix.

Clause 34D. The device of clause 33D, wherein the symmetry information includes value symmetry information that indicates value symmetry of the de-mix matrix.

Clause 35D. The device of any combination of clauses 33D and 34D, wherein the symmetry information includes sign symmetry information that indicates sign symmetry of the de-mix matrix.

Clause 36D. The device of any combination of clauses 29D-35D, further comprising means for interfacing with one or more microphones that captures audio data representative of the higher order ambisonic audio data.

Clause 37D. The device of any combination of clauses 29D-36D, wherein the legacy audio data includes stereo audio data that conforms to the stereo audio format, and includes a left channel and a right channel.

Clause 38D. The device of any combination of clauses 29D-36D, wherein the legacy audio data includes surround sound audio data that conforms to the 5.1 channel audio format, and includes a left channel, a right channel, a center channel, a back left channel, and a back right channel.

Clause 39D. The device of any combination of clauses 29D-38D, wherein the second portion of the higher order ambisonic audio data includes one or more coefficients corresponding to spherical basis functions to which one or more coefficients of the first portion of the higher order ambisonic audio data do not correspond.

Clause 40D. The device of any combination of clauses 29D-38D, wherein the first portion of the higher order ambisonic audio data comprises a first coefficient corresponding to a zero-order spherical basis function.

Clause 41D. The device of any combination of clauses 29D-38D, wherein the first portion of the higher order ambisonic audio data comprises a first coefficient corresponding to a zero-order spherical basis function, and a second coefficient corresponding to a first-order spherical basis function.

Clause 42D. The device of any combination of clauses 29D-38D, wherein the first portion of the higher order ambisonic audio data comprises a first coefficient corresponding to a zero-order spherical basis function, a second coefficient corresponding to a first-order, zero-sub-order spherical basis function, a third coefficient corresponding to a first-order negative-one-sub-order spherical basis function, and a fourth coefficient corresponding to a first-order, first-sub-order spherical basis function.

Clause 43D. A non-transitory computer-readable storage medium having stored thereon instructions that, when executed, cause one or more processors to: obtain mixing data that indicates how to process a first portion of higher order ambisonic audio data to obtain legacy audio data; process, based on the mixing data, the first portion of the higher order ambisonic audio data to obtain the legacy audio data; obtain de-mixing data that indicates how to process the legacy audio data to obtain the first portion of the higher order ambisonic audio data; specify, in the bitstream that includes a second portion of the higher order ambisonic audio data, the legacy audio data and the de-mixing data; and output the bitstream.

Moreover, as used herein, “A and/or B” means “A or B”, or both “A and B.”

Various aspects of the techniques have been described. These and other aspects of the techniques are within the scope of the following claims.

What is claimed is:

1. A device configured to process a bitstream representative of higher order ambisonic audio data, the device comprising:
one or more memories configured to store the higher order ambisonic audio data; and
one or more processors configured to:
obtain, from a bitstream, legacy audio data that conforms to a legacy audio format;
obtain, from the bitstream, de-mixing data that indicates how to process the legacy audio data to obtain a first portion of the higher order ambisonic audio data;
process, based on the de-mixing data, the legacy audio data to obtain the first portion of the higher order ambisonic audio data;
obtain, from the bitstream, a second portion of the higher order ambisonic audio data;
render the first portion of the higher order ambisonic audio data and the second portion of the higher order ambisonic audio data to obtain one or more speaker feeds; and
output the one or more speaker feeds to one or more speakers to reproduce a soundfield represented by the higher order ambisonic audio data.

2. The device of claim 1, wherein the one or more processors are configured to de-mix, based on the de-mix data, the legacy audio data to obtain the first portion of the higher order ambisonic audio data.

3. The device of claim 1, wherein the de-mix data includes de-mix data representative of a de-mix matrix.

4. The device of claim 1,
wherein the de-mix data includes de-mix data representative of a de-mix matrix that converts N input signals into M output signals, and
wherein N does not equal M.

5. The device of claim 3, wherein the de-mix data includes sparseness information indicative of a sparseness of the de-mix matrix.

6. The device of claim 3, wherein the de-mix data includes symmetry information that indicates a symmetry of the de-mix matrix.

7. The device of claim 6, wherein the symmetry information includes value symmetry information that indicates value symmetry of the de-mix matrix.

8. The device of claim 6, wherein the symmetry information includes sign symmetry information that indicates sign symmetry of the de-mix matrix.

9. The device of claim 1, wherein the first portion of the higher order ambisonic audio data comprises ambient higher order ambisonic audio data.

10. The device of claim 9,
wherein the one or more speakers include two speakers that provide stereo audio playback, and
wherein the legacy audio data includes stereo audio data that conforms to the stereo audio format, and includes a left channel and a right channel.

11. The device of claim 9,
wherein the one or more speakers include five speakers that provide surround sound audio playback, and
wherein the legacy audio data includes surround sound audio data that conforms to the 5.1 channel audio format, and includes a left channel, a right channel, a center channel, a back left channel, and a back right channel.

12. The device of claim 1, wherein the one or more processors are further configured to perform, in accordance with an AptX compression algorithm, psychoacoustic audio encoding with respect to encoded legacy audio data to obtain the legacy audio data.

13. The device of claim 1, wherein the first portion of the higher order ambisonic audio data comprises a first coefficient corresponding to a zero-order spherical basis function, a second coefficient corresponding to a first-order, zero-sub-order spherical basis function, a third coefficient corresponding to a first-order negative-one-sub-order spherical basis function, and a fourth coefficient corresponding to a first-order, first-sub-order spherical basis function.

14. A method of processing a bitstream representative of higher order ambisonic audio data, the method comprising:
obtaining, from the bitstream, legacy audio data that conforms to a legacy audio format;
obtaining, from the bitstream, de-mixing data that indicates how to recover a first portion of the higher order ambisonic audio data form the legacy audio data;
processing, based on the de-mixing data, the legacy audio data to obtain the first portion of the higher order ambisonic audio data;
obtaining, from the bitstream, a second portion of the higher order ambisonic audio data;
rendering the first portion of the higher order ambisonic audio data and the second portion of the higher order ambisonic audio data to obtain one or more speaker feeds; and
outputting the one or more speaker feeds to one or more speakers.

15. The method of claim 14, wherein processing the legacy audio data comprises de-mixing, based on the de-mix data, the legacy audio data to obtain the first portion of the higher order ambisonic audio data.

16. The method of claim 14, wherein the de-mix data includes de-mix data representative of a de-mix matrix.

17. The method of claim 14,
wherein the de-mix data includes de-mix data representative of a de-mix matrix that converts N input signals into M output signals, and
wherein N does not equal M.

18. The method of claim 16, wherein the de-mix data includes sparseness information indicative of a sparseness of the de-mix matrix.

19. The method of claim 16, wherein the de-mix data includes symmetry information that indicates a symmetry of the de-mix matrix.

20. The method of claim 19, wherein the symmetry information includes value symmetry information that indicates value symmetry of the de-mix matrix.

21. The method of claim 19, wherein the symmetry information includes sign symmetry information that indicates sign symmetry of the de-mix matrix.

22. The method of claim 14, wherein the first portion of the higher order ambisonic audio data comprises ambient higher order ambisonic audio data.

23. The method of claim 22,
wherein the one or more speakers include two speakers that provide stereo audio playback, and
wherein the legacy audio data includes stereo audio data that conforms to the stereo audio format, and includes a left channel and a right channel.

24. The method of claim 22,
wherein the one or more speakers include five speakers that provide surround sound audio playback, and
wherein the legacy audio data includes surround sound audio data that conforms to the 5.1 channel audio format, and includes a left channel, a right channel, a center channel, a back left channel, and a back right channel.

25. The method of claim 14, further comprising performing, in accordance with an AptX compression algorithm, psychoacoustic audio encoding with respect to encoded legacy audio data to obtain the legacy audio data.

26. The method of claim 14, wherein the first portion of the higher order ambisonic audio data comprises a first coefficient corresponding to a zero-order spherical basis function.

27. The method of claim 14, wherein the first portion of the higher order ambisonic audio data comprises a first coefficient corresponding to a zero-order spherical basis function, and a second coefficient corresponding to a first-order spherical basis function.

28. A device configured to obtain a bitstream representative of higher order ambisonic audio data, the device comprising:
one or more memories configured to store the higher order ambisonic audio data; and
one or more processors configured to:
obtain mixing data that indicates how to process a first portion of the higher order ambisonic audio data to obtain legacy audio data;
process, based on the mixing data, the first portion of the higher order ambisonic audio data to obtain the legacy audio data;
obtain de-mixing data that indicates how to process the legacy audio data to obtain the first portion of the higher order ambisonic audio data;
specify, in the bitstream that includes a second portion of the higher order ambisonic audio data, the legacy audio data and the de-mixing data; and
output the bitstream.

29. A method of obtaining a bitstream representative of higher order ambisonic audio data, the method comprising:
obtaining mixing data that indicates how to process a first portion of the higher order ambisonic audio data to obtain legacy audio data;
processing, based on the mixing data, the first portion of the higher order ambisonic audio data to obtain the legacy audio data;
obtaining de-mixing data that indicates how to process the legacy audio data to obtain the first portion of the higher order ambisonic audio data;
specifying, in the bitstream that includes a second portion of the higher order ambisonic audio data, the legacy audio data and the de-mixing data; and
outputting the bitstream.
